(19) United States
(12) Patent Application Publication
(10) Pub. No.: US 2026/0033386 A1
(43) Pub. Date: Jan. 29, 2026

(54) SEMICONDUCTOR PACKAGE COMPONENT, SEMICONDUCTOR PACKAGE STRUCTURE AND METHODS FOR FORMING THE SAME

(71) Applicant: TAIWAN SEMICONDUCTOR MANUFACTURING COMPANY LTD., HSINCHU (TW)

(72) Inventors: HARRY-HAK-LAY CHUANG, HSINCHU COUNTY (TW); WEI-CHENG WU, HSINCHU COUNTY (TW); FANG-LAN CHU, TAICHUNG CITY (TW); CHIH-PENG TSAI, CHANGHUA COUNTY (TW)

(21) Appl. No.: 18/786,629

(22) Filed: Jul. 29, 2024

(51) Int. Cl. H01L 25/065; H01L 21/78; H01L 23/00; H01L 23/58

(52) U.S. Cl. CPC H01L 25/0657; H01L 21/78; H01L 23/585; H01L 24/05; H01L 2224/05647; H01L 2924/35121

(57) ABSTRACT

A method for forming a semiconductor package structure includes following operations. A first semiconductor wafer is received. The first semiconductor wafer includes a first front side and a first backside. The first semiconductor wafer has a first central region and a first peripheral region. The first semiconductor wafer includes a first interconnect structure in the first central region on the first front side, a first ring structure in the first peripheral region on the first front side, and a first bonding layer over the first ring structure and the first interconnect structure on the first front side. A second semiconductor wafer is received. The second semiconductor wafer has a second front side and a second backside. The second semiconductor wafer includes a second bonding layer disposed on the second front side. The first bonding layer is bonded to the second bonding layer.

### BACKGROUND

High densities of electronic components may be achieved by fabricating three-dimensional (3D) integrated circuit (IC) device structures. Some 3D device structures, such as wafer-on-wafer (WoW) structures, are formed by stacking and bonding multiple IC devices (i.e., chips) at a semiconductor component level. Such 3D bonded wafer device structures may provide improved integration density and other advantages, such as greater speeds and greater bandwidths, due to decreased lengths of interconnects between the stacked chips.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a semiconductor package component in accordance with aspects of the present disclosure in one or more embodiments.

FIG. 1B is an enlarged cross-sectional view of the semiconductor package component taken along line I-I′ in FIG. 1A in accordance with aspects of the present disclosure in one or more embodiments.

FIG. 2 is a schematic drawing illustrating a semiconductor package component in a wafer edge exposure (WEE) operation in accordance with aspects of the present disclosure in one or more embodiments.

FIGS. 3A to 3J are cross-sectional views of various stages in a formation of a semiconductor package component in accordance with aspects of the present disclosure in one or more embodiments.

FIG. 4 is a cross-sectional view of a semiconductor package component in accordance with aspects of the present disclosure in one or more embodiments.

FIG. 5 is a cross-sectional view of a semiconductor package component in accordance with aspects of the present disclosure in one or more embodiments.

FIGS. 6A to 6J are cross-sectional views of various stages in a formation of a semiconductor package component in accordance with aspects of the present disclosure in one or more embodiments.

FIGS. 7A to 7C are cross-sectional views of various stages in a formation of a semiconductor package component in accordance with aspects of the present disclosure in one or more embodiments.

FIG. 8 is a cross-sectional view of a semiconductor package component in accordance with aspects of the present disclosure in one or more embodiments.

FIGS. 9 to 12 are cross-sectional views of various stages in a formation of a semiconductor package structure in accordance with aspects of the present disclosure in one or more embodiments, wherein FIGS. 10A to 10C respectively illustrate an intermediate semiconductor package structure in accordance with aspects of the present disclosure in different embodiments.

FIG. 13 is a flowchart representing a method for forming a semiconductor package structure in accordance with aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective test measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

An integrated circuit (IC) chip incorporates millions of active and passive electrical components on a semiconductor substrate within an area, which may be referred to as a die. Layers of materials are deposited, implanted, patterned, and/or removed in order to form the active and passive electrical components and interconnection structures of the IC chip. Usually, tens or even hundreds of similar or identical IC chips are arranged to be manufactured on a single wafer for efficient mass production. The greater the wafer size, the more IC chips can be manufactured on a single wafer, thus reducing the fabrication cost for each IC chip.

An edge portion of the wafer tends to be more vulnerable to damage caused by the handling of automated robot arms, various types of process variation, such as poor step coverage during forming of films thereon, trapped voids when filling openings, or damage caused by material exposure, plasma-arcing, or other uniformity issues of manufacturing processes. Such issues not only result in defective chips at the edge portion of the wafer, but also may lead to more defective chips at inner portions of the wafer when cracks or delamination at the edge portion propagate inward toward the center of the wafer.

In accordance with some embodiments, the present disclosure provides semiconductor package components, semiconductor package structures and methods for forming the semiconductor package structures, particularly wafer-on-wafer (WoW) package structures. In some embodiments, the WoW package structure has a metallic edge ring formed during or after a forming of a back-end-of-line (BEOL) interconnect structure. The metallic edge ring helps prevent cracks or delamination from propagating inward to dies. In some embodiments, to achieve such metallic edge ring scheme, a wafer edge exposure (WEE) operation may be performed.

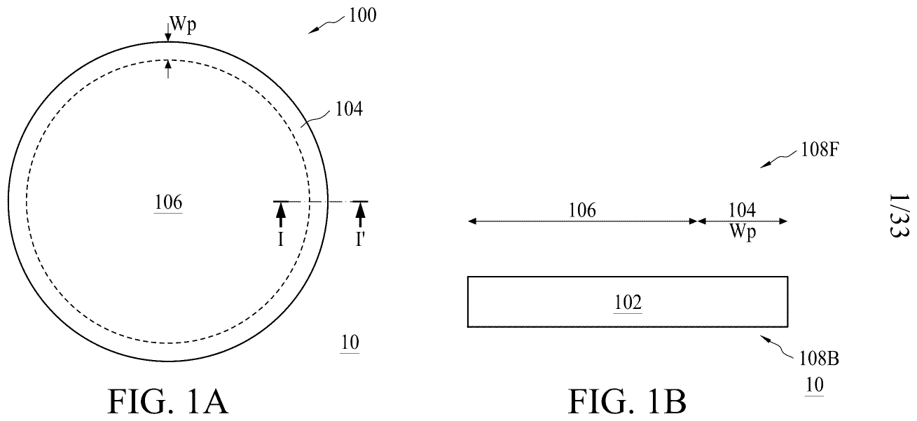

Please refer to FIGS. 1A and 1B, wherein FIG. 1A is a top view of a semiconductor wafer 100, and FIG. 1B is an enlarged cross-sectional view of the semiconductor wafer 100 taken along line I-I′ in FIG. 1A in accordance with one or more embodiments. The semiconductor wafer 100 has a substrate 102.

As shown in FIGS. 1A and 1B, the semiconductor wafer 100 may be defined to have a peripheral region 104 and a central region 106 encircled by the peripheral region 104. The peripheral region 104 is a region defined near an edge or a circumference of the semiconductor wafer 100. In some embodiments, the peripheral region 104 may be used to define a boundary for the semiconductor wafer 100. In some embodiments, the central region 106 inside the peripheral region 104 may be used to form a plurality of dies where integrated circuits (IC) are manufactured. In some embodiments, the peripheral region 104 is free of dies or functional devices/components. In some embodiments, a width Wp of the peripheral region 104 may be equal to or less than 3 millimeters (mm), but the disclosure is not limited thereto.

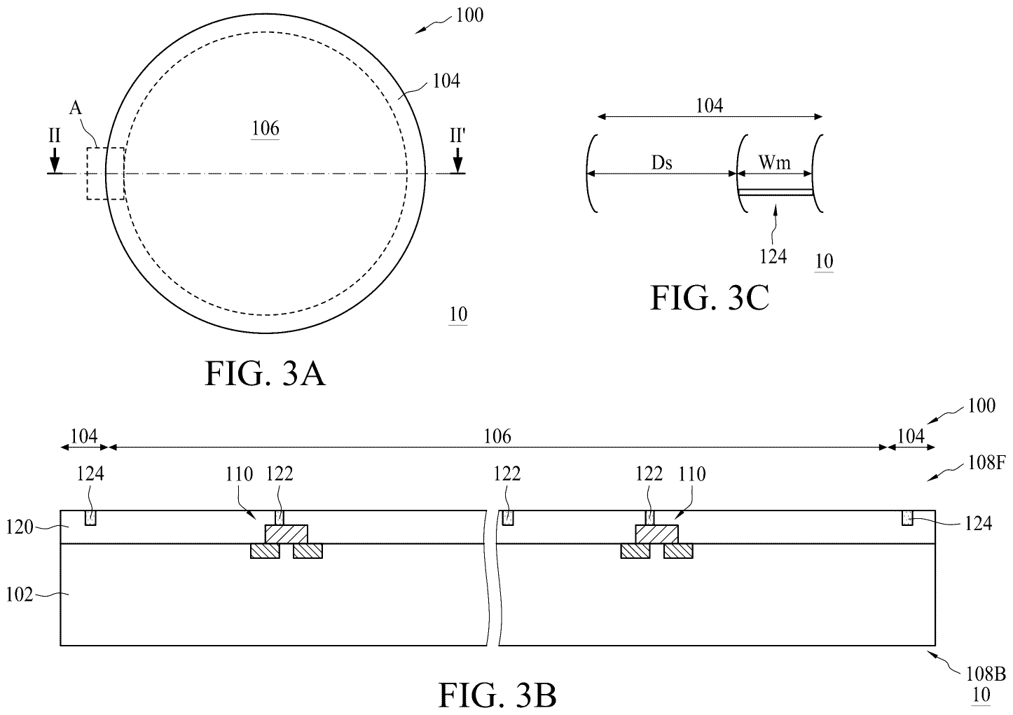

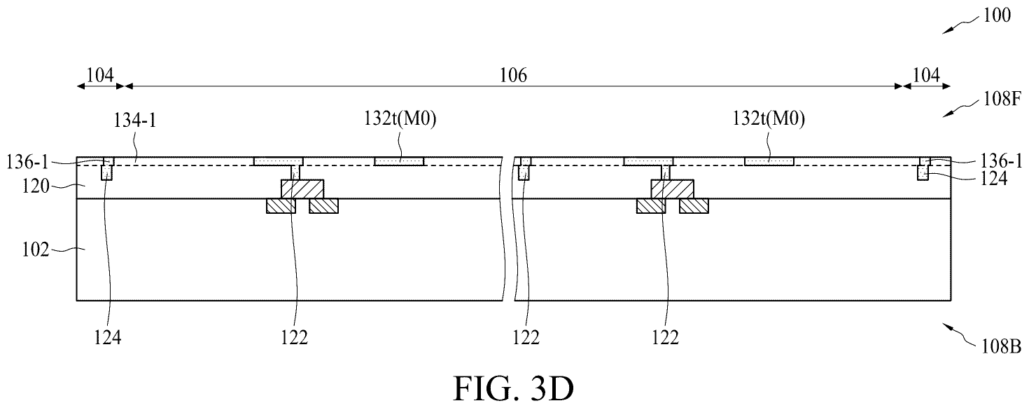

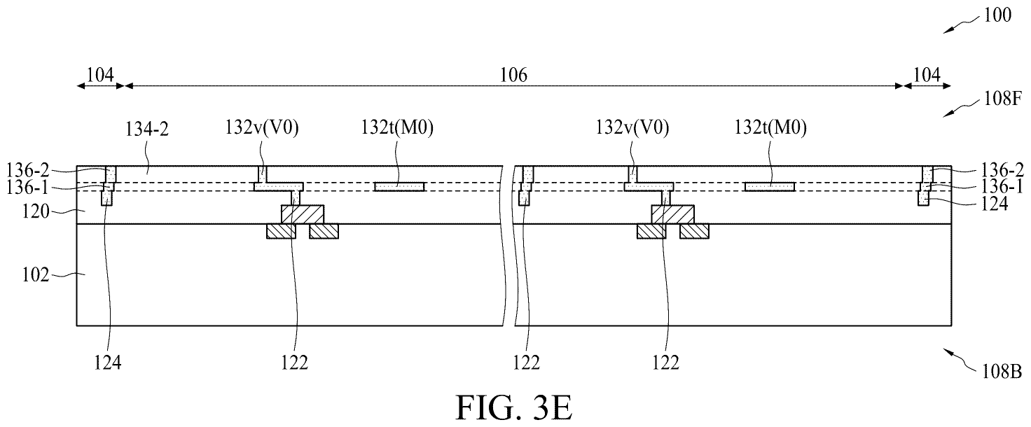

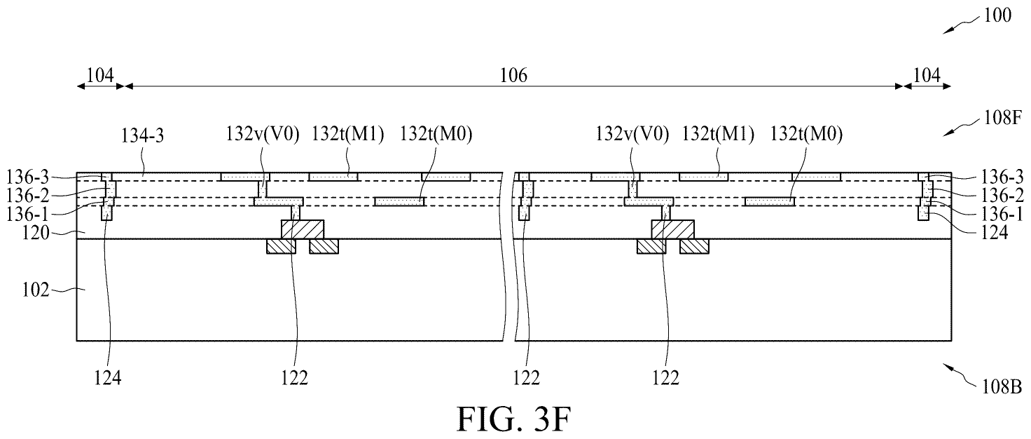

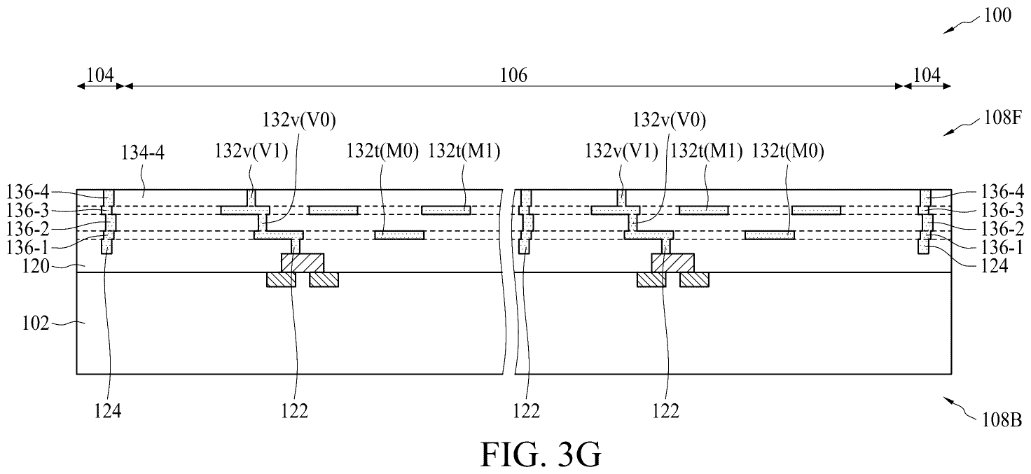

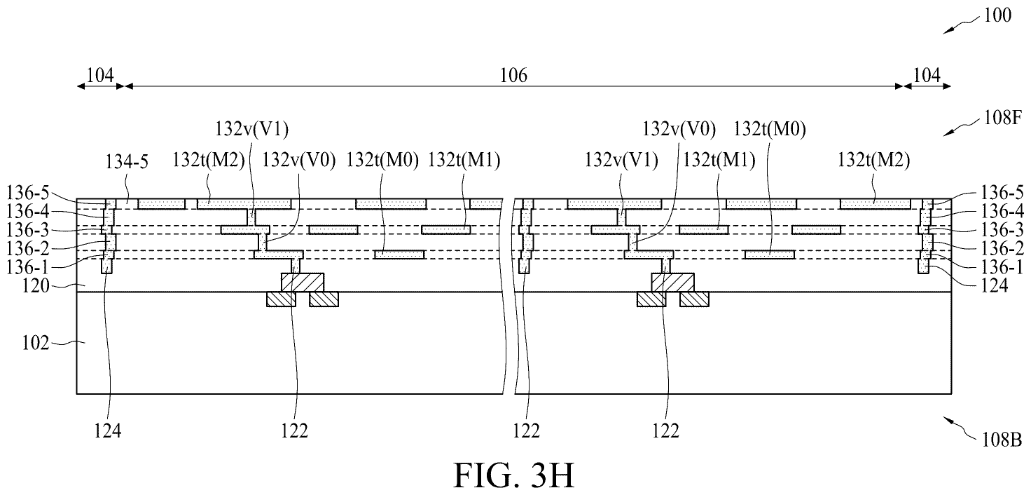

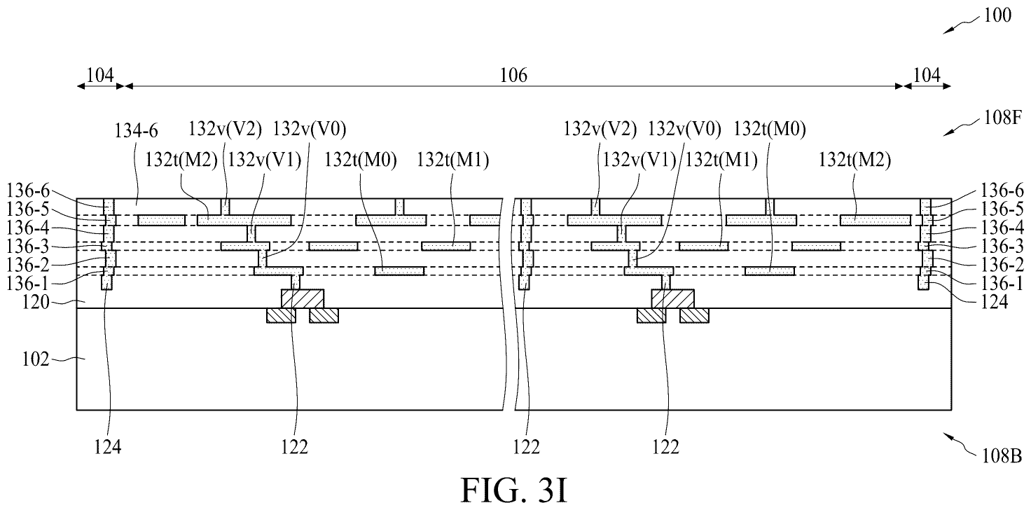

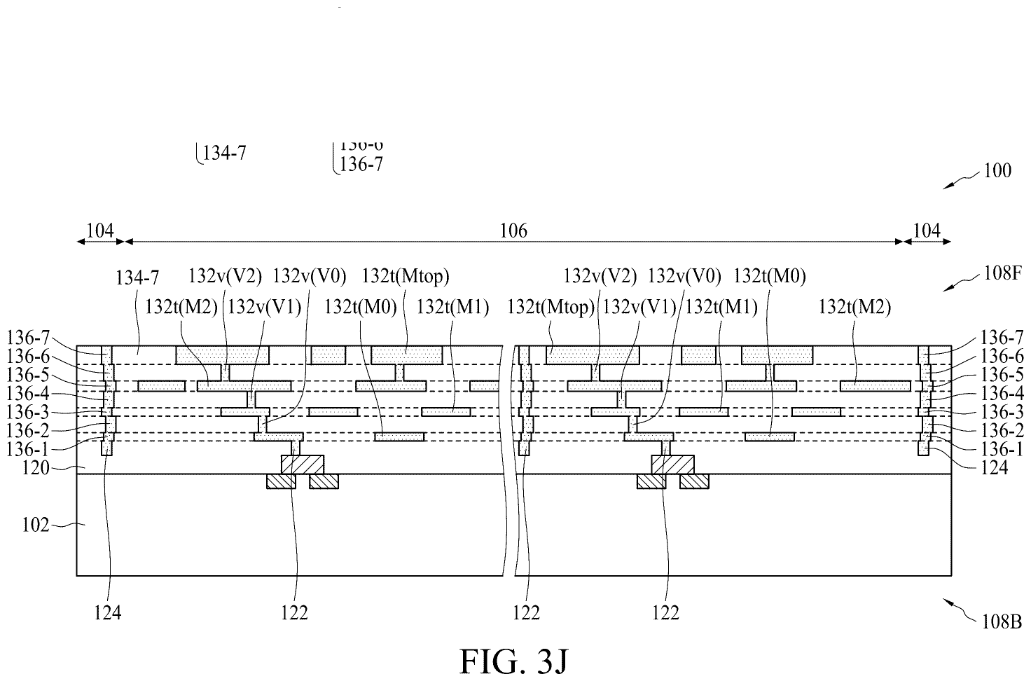

The substrate 102 may have any construction including semiconductor materials, including, but not limited to, bulk silicon, a semiconductor component, a silicon-on-insulator (SOI) substrate, or a silicon germanium substrate. Other semiconductor materials including group III, group IV, and group V elements may also be used. The substrate 102 may include an active surface on a first side (i.e., a front side) 108F, and a second side (i.e., a backside) 108B opposite to the first side 108F. In some embodiments, the substrate 102 may further include a plurality of isolation features (not shown), such as shallow trench isolation (STI) features or local oxidation of silicon (LOCOS) features formed therein on the front side 108F. The isolation features may define and isolate active regions in the substrate 102. Various microelectronic elements 110 (shown in FIG. 3B) may be formed in the substrate 102 on the front side 108F. Further, the various microelectronic elements 110 are formed in the central region 106. For example, the various microelectronic elements 110 are formed in die regions in the central region 106. Examples of the various microelectronic elements 110 include transistors (e.g., metal-oxide-semiconductor field-effect transistors (MOSFET), complementary metal-oxide-semiconductor (CMOS) transistors, bipolar junction transistors (BJT), high-voltage transistors, high-frequency transistors, p-channel and/or n-channel field-effect transistors (PFETs/NFETs), etc.); resistors; diodes; capacitors; inductors; fuses; and other suitable elements. Various processes are performed to form the various microelectronic elements 110 including deposition, etching, implantation, photolithography, annealing, and other suitable processes. The microelectronic elements 110 are interconnected to form an integrated circuit device. The integrated circuit device can be a logic device, a memory device (e.g., an SRAM), an RF device, an input/output (I/O) device, a system-on-chip (SoC) device, combinations thereof, and other suitable types of devices.

In some embodiments, the above-mentioned microelectronic elements 110 may be formed by front-end-of-line (FEOL) operations, and details thereof are omitted for brevity. In some embodiments, the semiconductor wafer 100 is an intermediate product 10 for manufacturing a package component.

In some embodiments, the semiconductor wafer 100 is received for further operations. In such embodiments, a material layer (not shown) is formed over the substrate 102 on the front side 108F. For example, the semiconductor wafer 100 is received for a middle-end-of-line (MEOL) operation, and a dielectric layer 120 (shown in FIG. 3B) is formed over the substrate 102. In some embodiments, the dielectric layer 120 may include an inter-layer dielectric (ILD) layer. The ILD layer 120 is formed over the substrate 102 on the front side 108F, and fills spaces between the various microelectronic elements 110. In some embodiments, the ILD layer 120 may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), and/or other suitable dielectric materials. Although not shown in the figures, a contact etch stop layer (CESL) may be deposited before the ILD layer 120 is deposited, such that the CESL is disposed between the ILD layer 120 and the underlying structures. The CESL may include silicon nitride or silicon oxynitride.

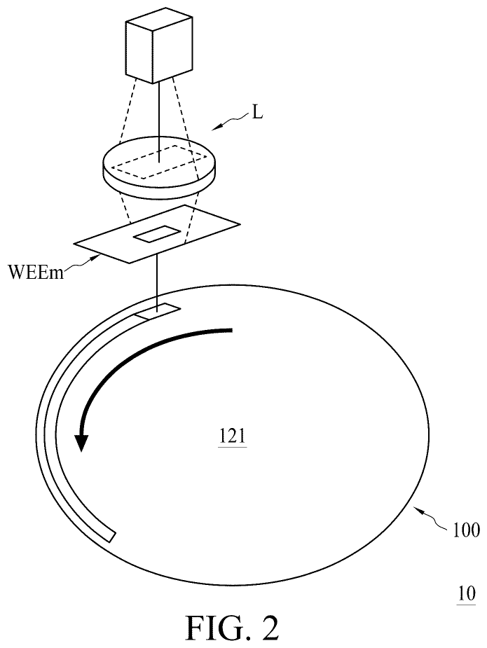

Referring to FIG. 3B, in some embodiments, a plurality of connecting structures 122 and 124 serving as contact plugs are formed in the ILD layer 120 during the MEOL operation and electrically connect the various microelectronic elements 110. In some embodiments, the forming of the connecting structures 122 and 124 includes forming a photoresist layer 121 (shown in FIG. 2) over the substrate 102 on the front side 108F and performing a photolithography operation to pattern the photoresist layer 121. The photolithography operation includes an exposure operation in which a photoresist is exposed to a pattern of intense light, and a developing operation in which the areas of the pattern exposed to the light undergo a chemical change that allows some of the photoresist to be removed by a special solution. In some embodiments, the exposure operation is performed such that a pattern including the connecting structures 122 is transferred to the photoresist in the central region 106. In some embodiments, a wafer edge exposure (WEE) operation is performed to transfer a pattern including the plurality of connecting structures 124 in the peripheral region 104.

Please refer to FIG. 2, wherein FIG. 2 is a schematic drawing illustrating the intermediate semiconductor package component 10 during a WEE operation in accordance with aspects of the present disclosure in one or more embodiments. In some embodiments, the photoresist layer 121 in the peripheral region 104 undergoes to the WEE operation. In the WEE operation, a beam of light L is provided to the photoresist layer 121 in the peripheral region 104. In some embodiments, the light L is emitted from mercury lights. Other types of light sources and light having different wavelengths are within the scope of various embodiments. Exemplary light sources include I-line lights, KrF lights and ArF lights, which have respective wavelengths of 365 nm, 248 nm, and 193 nm. Light propagating through water using an immersion technology and electron beams are also within the scope of various embodiments. Properties of the photoresist layer 121 in the peripheral region 104 are changed during illumination by the lights L. A portion of the photoresist layer 121 in the central region 106 is not subjected to the light L, and therefore maintains previous property characteristics. The WEE process prevents the photoresist layer 121 in the central region 106 from being patterned when the photoresist layer 121 in the peripheral region 104 is patterned.

In some embodiments, the WEE operation is performed on the peripheral region 104 prior to the performing of the exposure operation on the central region 106. In some alternative embodiments, the WEE operation is performed on the peripheral region 104 after the performing of the exposure operation on the central region 106.

In some embodiments, after the WEE operation is performed on the photoresist layer 121 in the peripheral region 104 and the exposure operation is performed on the photoresist layer 121 in the central region 106, a developing operation is performed such that the patterns including the connecting structures 122 in the central region 106 and the patterns including the connecting structures 124 in the peripheral region 104 are transferred to the photoresist layer 121.

Please refer to FIGS. 3A to 3C, wherein FIG. 3B is a cross-sectional view taken along line II-II′ of FIG. 3A, and FIG. 3C is a partially enlarged view of frame A in FIG. 3A. In some embodiments, the patterns in the photoresist layer 121 are transferred to the dielectric layer 120 to form a plurality of openings (not shown) by a suitable etch operation. Subsequently, a conductive material is deposited over the substrate 102 and fills the openings. The conductive material may include ruthenium (Ru), cobalt (Co), nickel (Ni), tungsten (W), copper (Cu), or other metals, as examples. In some embodiments not explicitly shown, a barrier layer may be formed prior to the forming of the conductive material. Such a barrier layer may include a metal nitride, such as titanium nitride, tantalum nitride, tungsten nitride, cobalt nitride, or nickel nitride. Additionally, in order to reduce contact resistance, a silicide feature may be formed over a source/drain feature prior to the forming of the barrier layer, the conductive material, and/or the dielectric layer 120.

Next, a planarization operation is performed to remove superfluous conductive material. Accordingly, the plurality of connecting structures 122 are formed in the central region 106, and the plurality of connecting structures 124 are formed in the peripheral region 104. As shown in FIGS. 3A and 3B, the connecting structures 122 in the central region 106 are electrically connected to the various microelectronic elements 110, while the connecting structures 124 in the peripheral region 104 are electrically and physically isolated from the connecting structures 122 and the various microelectronic elements 110. Additionally, in some embodiments, the connecting structures 124 are electrically and physically separated from the substrate 102.

Referring to FIG. 3C, in some embodiments, the connecting structures 124 in the peripheral region 104 are spaced apart from the edge/circumference of the substrate 102 by a distance Ds. In some embodiments, the distance Ds is equal to or less than 2.5 mm, but the disclosure is not limited thereto. Further, the connecting structure 124 has a width Wm. In some embodiments, the width Wm of the connecting structure 124 is between approximately 0.5 micrometer (m) and approximately 0.5 mm. For example, the width Wm of the connecting structure 124 may be approximately 1 μm, but the disclosure is not limited thereto.

In some embodiments, after the MEOL operation, a back-end-of-line (BEOL) interconnect structure 130 electrically connected to the various microelectronic elements 110 is formed. The interconnect structure 130 includes metal lines 132t and vias 132v, which are formed in dielectric layers 134 (also referred to as inter-metal dielectrics (IMDs)). The metal lines 132t at a same level are collectively referred to herein as a metallization layer 132t. In accordance with some embodiments, the BEOL interconnect structures 130 includes a plurality of metallization layers 132t including the metal lines that are interconnected through the vias 132v. In some embodiments, the dielectric layer 134 may include a low dielectric constant or an extreme low dielectric constant (ELK) material, such as an oxide, SiO₂, borophosphosilicate glass (BPSG), TEOS, spin on glass (SOG), undoped silicate glass (USG), fluorinated silicate glass (FSG), high-density plasma (HDP) oxide, or plasma-enhanced TEOS (PETEOS). In some embodiments, the metallization layers 132t and the vias 132v may be formed of any suitable conductive material, such as a highly-conductive metal, low-resistive metal, elemental metal, transition metal, or the like. In some embodiments, the metallization layers 132t and the vias 132v may be formed of copper, although other materials, such as tungsten, aluminum, gold, or the like, may alternatively be utilized.

Please refer to FIG. 3D, which is a cross-sectional view in a stage subsequent to that shown in FIG. 3B. In some embodiments, the forming of the interconnect structure 130 includes forming a dielectric layer 134-1 over the substrate 102 on the front side 108F. A photoresist layer (not shown) is formed over the dielectric layer 134-1. The photoresist layer is patterned by using an exposure operation and a WEE operation, followed by a developing operation. The exposure operation, the WEE operation and the developing operation may be similar to those described above; therefore, details thereof are omitted for brevity. In some embodiments, the patterns in the photoresist layer are next transferred to the dielectric layer 134-1 to form a plurality of openings (not shown), a conductive material is deposited to fill the openings, and a planarization is performed to remove superfluous conductive material. Accordingly, a plurality of metallization layers 132t are formed in the central region 106, and a plurality of metallization layers 136-1 are formed in the peripheral region 104. In some embodiments, the metallization layer 132t, which is the bottommost metallization layer and nearest to the FEOL devices, may be designated as M0, as shown in FIG. 3D.

Still referring to FIG. 3D, in some embodiments, the metallization layer 136-1 in the peripheral region 104 is spaced apart from the edge of the substrate 102 by a distance Ds. In some embodiments, the distance Ds is equal to or less than 2.5 mm, but the disclosure is not limited thereto. Further, the metallization layer 136-1 has a width, and the width may be equal to the width Wm of the connecting structure 124. In some embodiments, a location of the metallization layer 136-1 is similar to that of the connecting structure 124. Accordingly, the metallization layer 136-1 is substantially aligned with the connecting structure 124. In other words, the metallization layer 136-1 may overlap the connecting structure 124, as shown in FIG. 3D.

Please refer to FIG. 3E, which is a cross-sectional view in a stage subsequent to that shown in FIG. 3D. In some embodiments, the forming of the interconnect structure 130 further includes forming a dielectric layer 134-2 over the substrate 102 on the front side 108F. A photoresist layer (not shown) is formed over the dielectric layer 134-2. The photoresist layer is patterned using an exposure operation and a WEE operation, followed by a developing operation. The exposure operation, the WEE operation and the developing operation may be similar to those described above; therefore, details thereof are omitted for brevity. In some embodiments, the patterns in the photoresist layer are next transferred to the dielectric layer 134-2 to form a plurality of openings (not shown), a conductive material is deposited to fill the openings, and a planarization is performed to remove superfluous conductive material. Accordingly, a plurality of vias 132v are formed in the central region 106, and a plurality of metallization layers 136-2 are formed in the peripheral region 104. In some embodiments, the vias 132v that are directly over the bottommost metallization layer M0 may be designated as V0, as shown in FIG. 3E.

Still referring to FIG. 3E, in some embodiments, the metallization layer 136-2 in the peripheral region 104 is spaced apart from the edge of the substrate 102 by a distance Ds. In some embodiments, the distance Ds is equal to or less than 2.5 mm, but the disclosure is not limited thereto. Further, the metallization layer 136-2 has a width, and the width may be equal to the width Wm of the connecting structure 124. In some embodiments, the metallization layer 136-2 is substantially aligned with the connecting structure 124 and the metallization layer 136-1. In other words, the metallization layer 136-2 may overlap the metallization layer 136-1 and the connecting structure 124, as shown in FIG. 3E.

Please refer to FIG. 3F, which is a cross-sectional view in a stage subsequent to that shown in FIG. 3E. In some embodiments, the forming of the interconnect structure 130 includes forming a dielectric layer 134-3 over the substrate 102 on the front side 108F. A photoresist layer (not shown) is formed over the dielectric layer 134-3. The photoresist layer is patterned using an exposure operation and a WEE operation, followed by a developing operation. The exposure operation, the WEE operation and the developing operation may be similar to those described above; therefore, details thereof are omitted for brevity. In some embodiments, the patterns in the photoresist layer are next transferred to the dielectric layer 134-3 to form a plurality of openings (not shown), a conductive material is deposited to fill the openings, and a planarization is performed to remove superfluous conductive material. Accordingly, a plurality of metallization layers 132t are formed in the central region 106, and a plurality of metallization layers 136-3 are formed in the peripheral region 104. In some embodiments, the metallization layer 132t that is formed directly on the vias V0 may be designated as M1, as shown in FIG. 3F.

Still referring to FIG. 3F, in some embodiments, the metallization layer 136-3 in the peripheral region 104 is spaced apart from the edge of the substrate 102 by a distance Ds. In some embodiments, the distance Ds is equal to or less than 2.5 mm, but the disclosure is not limited thereto. Further, the metallization layer 136-3 has a width, and the width may be equal to the width Wm of the connecting structure 124. In some embodiments, the metallization layer 136-3 is substantially aligned with the metallization layer 136-2, the metallization layer 136-1 and the connecting structure 124. In other words, the metallization layer 136-3 may overlap the metallization layer 136-2, the metallization layer 136-1 and the connecting structure 124, as shown in FIG. 3F.

In some embodiments, the metallization layer M1 and the vias V0 may be formed by a dual damascene operation. In such embodiments, the metallization layers 136-3 and 136-2 may be formed simultaneously.

Referring to FIG. 3G, in some embodiments, the forming of the interconnect structure 130 includes forming a dielectric layer 134-4, and forming a plurality of vias 132v in the dielectric layer 134-4 in the central region 106 and a plurality of metallization layers 136-4 in the dielectric layer 134-4 in the peripheral region 104. In some embodiments, the vias 132v that are directly over the metallization layer M1 may be designated as V1, as shown in FIG. 3G. Operations for forming the vias V1 and the metallization layer 136-4 may be similar to those described above; therefore, details thereof are omitted for brevity. In some embodiments, a dimension and an arrangement of the metallization layers 136-4 are similar to those described above; therefore, details thereof are omitted for brevity.

Referring to FIG. 3H, in some embodiments, the forming of the interconnect structure 130 includes forming a dielectric layer 134-5, and forming a plurality of f metallization layers 132t in the dielectric layer 134-5 in the central region 106 and a plurality of metallization layers 136-5 in the dielectric layer 134-5 in the peripheral region 104. In some embodiments, the metallization layers 132t that are directly over the vias V1 may be designated as M2, as shown in FIG. 3H. Operations for forming the metallization layers M2 and the metallization layers 136-5 may be similar to those described above; therefore, details thereof are omitted for brevity. In some embodiments, a dimension and an arrangement of the metallization layers 136-5 are similar to those described above; therefore, details thereof are omitted for brevity.

In some embodiments, the metallization layer M2 and the vias V1 may be formed by a dual damascene operation. In such embodiments, the metallization layers 136-4 and 136-5 may be formed simultaneously.

Referring to FIG. 3I, in some embodiments, the forming of the interconnect structure 130 includes forming a dielectric layer 134-6, and forming a plurality of vias 132v in the dielectric layer 134-6 in the central region 106 and a plurality of metallization layers 136-6 in the dielectric layer 134-6 in the peripheral region 104. In some embodiments, the vias 132v that are directly over the metallization layer M2 may be designated as V2, as shown in FIG. 3I. Operations for forming the vias V2 and the metallization layer 136-6 may be similar to those described above; therefore, details thereof are omitted for brevity. In some embodiments, a dimension and an arrangement of the metallization layers 136-6 are similar to those described above; therefore, details thereof are omitted for brevity.

Referring to FIG. 3J, in some embodiments, the forming of the interconnect structure 130 includes forming a dielectric layer 134-7, and forming a plurality of metallization layers 132t in the dielectric layer 134-7 in the central region 106 and a plurality of metallization layers 136-7 in the dielectric layer 134-7 in the peripheral region 104. In some embodiments, the metallization layers 132t that are directly over the vias V2 may be designated as Mn. In some embodiments, when the metallization layers 132t are the topmost layers of all metallization layers M0, M1 and M2, such metallization layers 132t may be designated as Mtop, as shown in FIG. 3J. Operations for forming the metallization layers Mtop and the metallization layer 136-7 may be similar to those described above; therefore, details thereof are omitted for brevity. In some embodiments, a dimension and an arrangement of the metallization layers 136-7 are similar to those described above; therefore, details thereof are omitted for brevity.

Additionally, the interconnect structure 130 may be formed in each of die regions in the central region 106. Further, in some embodiments, a die seal ring (not shown) may be formed in each of the die regions during the forming of the interconnect structure 130. In some embodiments, the die seal ring may be formed around one or more of the dies on the semiconductor component 100, thereby providing die-level protection for the dies within each die seal ring.

In some embodiments, the metallization layer Mn and the vias V2 may be formed by a dual damascene operation. In such embodiments, the metallization layers 136-6 and 136-7 may be formed simultaneously.

Still referring to FIG. 3J, which illustrates an intermediate semiconductor package component 11, an interconnect structure 130 is formed in the central region 106, while a metallic edge ring 140 is formed in the peripheral region 104. Further, the metallic edge ring 140 encircles the interconnect structure 130. In such embodiments, the interconnect structure 130 and the metallic edge ring 140 are simultaneously formed. In some embodiments, a portion of the metallic edge ring 140 (i.e., the connecting structure 124) has a material same as that of the connecting structure 122. In some embodiments, a portion of the metallic edge ring 140 (i.e., the metallization layers 136-1 to 136-7) has a material same as that of the interconnect structure 130.

In some embodiments, the metallic edge ring 140 includes the connecting structure 124 formed in the MEOL operations and the metallization layers 136-1 to 136-7 formed in the BEOL operation. In some embodiments, the metallic edge ring 140 is electrically and physically isolated from the BEOL interconnect structure 130 in the central region 106, and electrically and physically isolated from the substrate 102. The metallic edge ring 140 is disposed in the peripheral region 104 of the semiconductor wafer 100 of the intermediate semiconductor package component 11. A width of the metallic edge ring 140 is between approximately 0.5 μm and approximately 0.5 mm. For example, the width of the metallic edge ring 140 may be approximately 1 μm, but the disclosure is not limited thereto. In some embodiments, the width of the metallic edge ring 140 is consistent. However, in some alternative embodiments, the width of the metallic edge ring 140 may be inconsistent, and thus sidewalls of the metallic edge ring 140 may have a zigzag configuration. In some embodiments, the metallic edge ring 140 is spaced apart from the edge of the semiconductor component 100 by a distance Ds. In some embodiments, the distance Ds is equal to or less than 2.5 mm, but the disclosure is not limited thereto.

It should be noted that the metallic edge ring 140 is different from the die seal ring. As mentioned above, the die seal ring is formed in each of the die regions, while the metallic edge ring 140 is formed surrounding all of the die regions. In other words, the metallic edge ring 140 also surrounds all of the die seal rings, but is electrically and physically isolated from the die seal rings. The die seal ring provides die-level protection for the dies in the central region 106, while the metallic edge ring 140 in the peripheral region 104 provides wafer-level protection, which will be described later. In some embodiments, the width of the metallic edge ring 140 is greater than a width of the die seal ring. In some embodiments, a height of the metallic edge ring 140 may be equal to or greater than a height of the die seal ring, but the disclosure is not limited thereto.

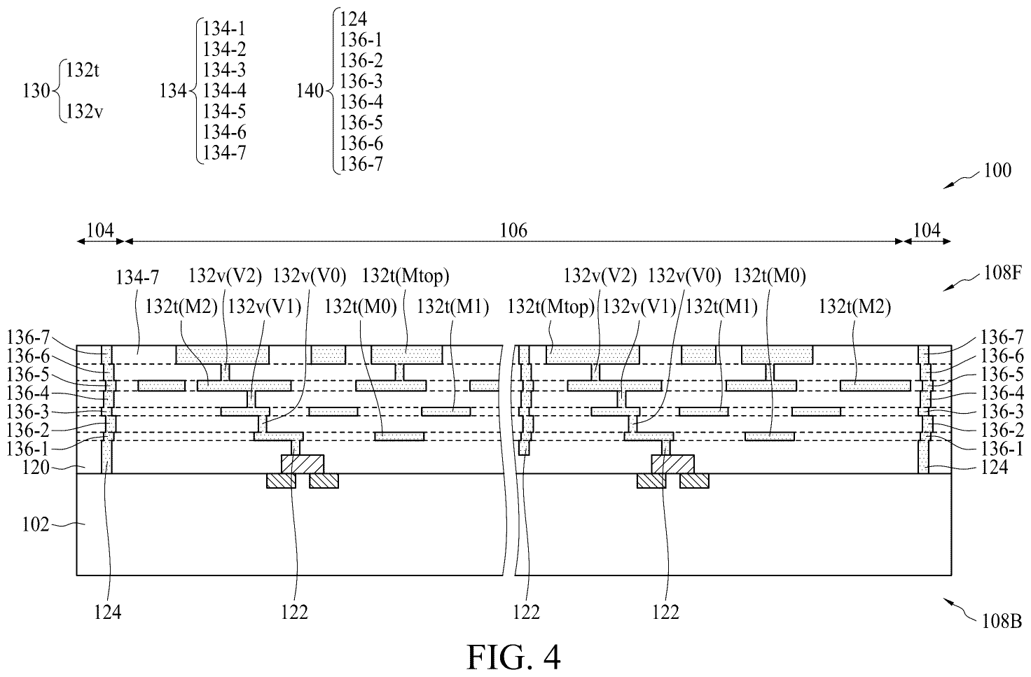

As shown in FIG. 3J, in some embodiments, a bottom surface and the sidewalls of the metallic edge ring 140 are in contact with the dielectric layer 134. However, in some embodiments, by adjusting an etch operation in the MEOL operation, a portion of the metallic edge ring 140 (i.e., the connecting structure 124) may be in contact with the substrate 102, as shown in FIG. 4. In such embodiments, the connecting structure 124 may be formed simultaneously with the forming of a connecting structure that is in contact with a source/drain region. Additionally, in such embodiments, a height of the metallic edge ring 140 is greater than the heights of the die seal rings.

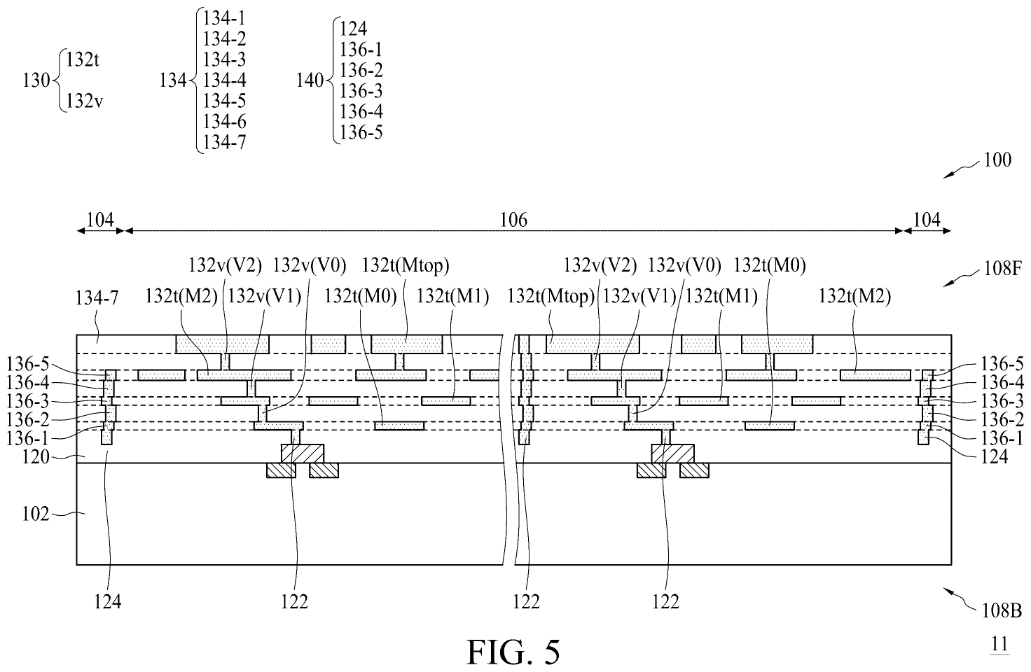

In some embodiments, by adjusting the BEOL operation, the metallic edge ring 140 can be formed entirely in the dielectric layers 134. For example, in some embodiments, during the forming of the vias V2 and the forming of the metallization layers Mtop, the WEE operation may be omitted. Therefore, the metallic edge ring 140 includes the connecting structure 124 and the metallization layers 136-1 to 136-5, as shown in FIG. 5. In such embodiments, the sidewalls, a top and the bottom of the metallic edge ring 140 are all in contact with the dielectric layer 134. In such embodiments, the metallic edge ring 140 can be described as floating in the dielectric layer 134 and thus the top of the metallic edge ring 140 is separated from other elements (e.g., a to-be-formed bonding layer). Additionally, in such embodiments, the height of the metallic edge ring 140 may be equal to or less than the heights of the die seal rings.

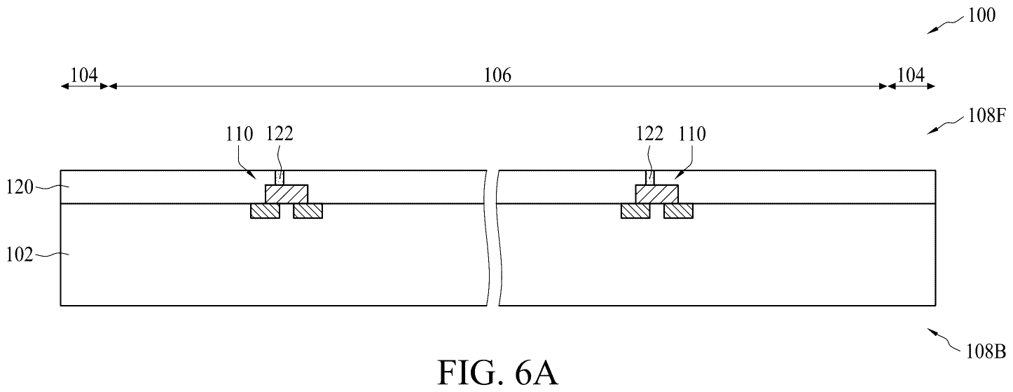

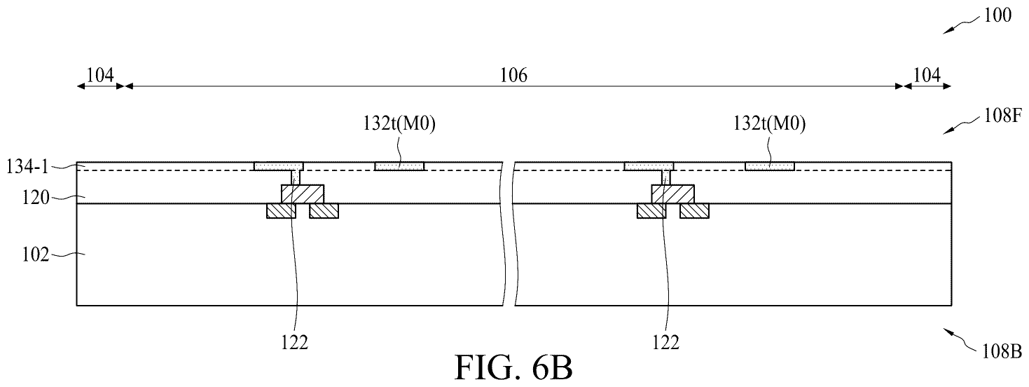

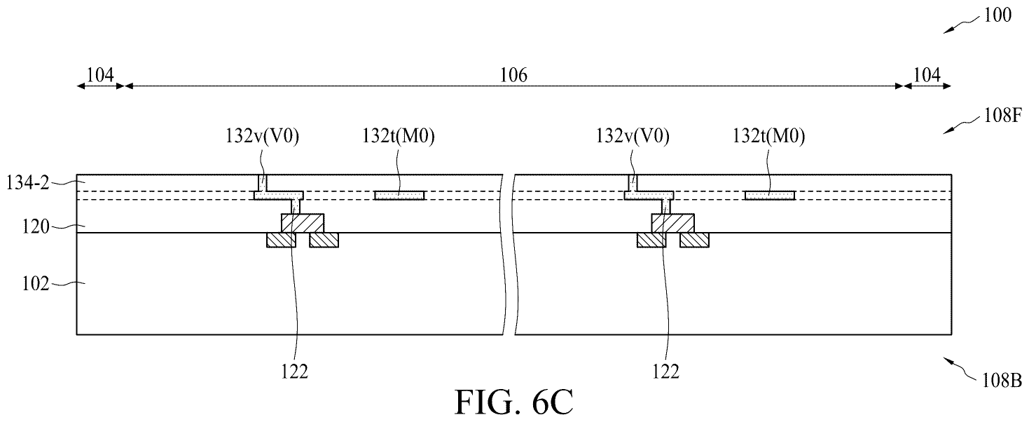

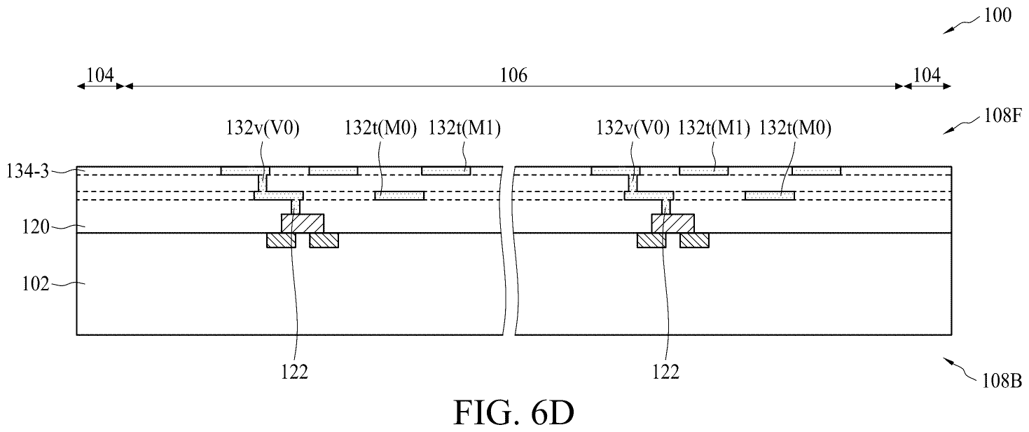

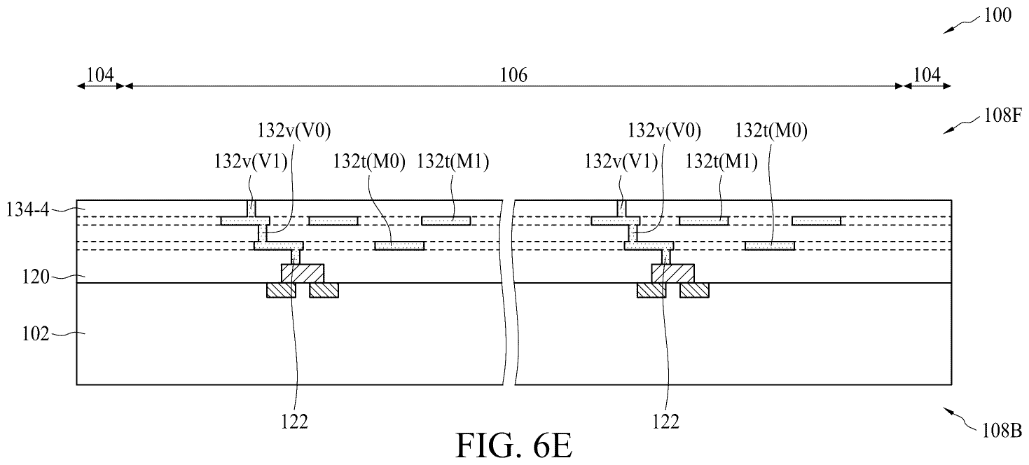

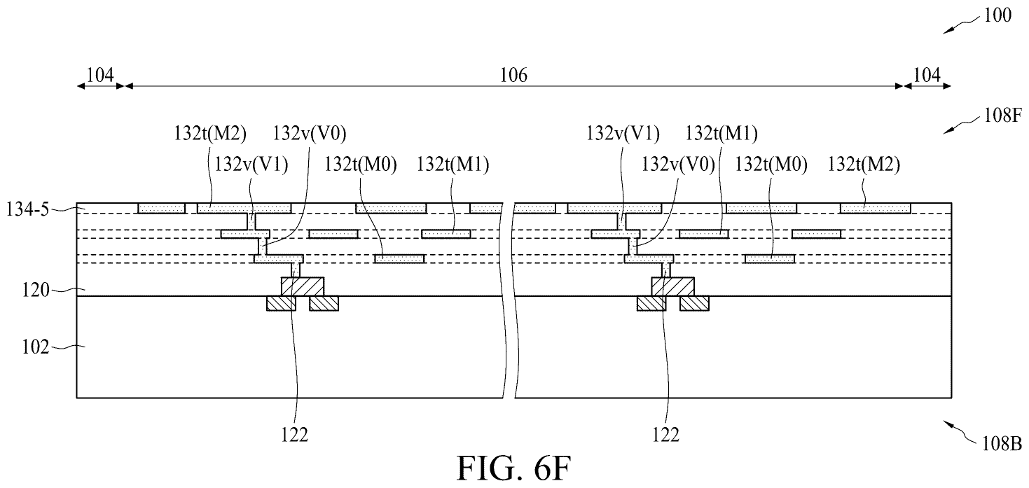

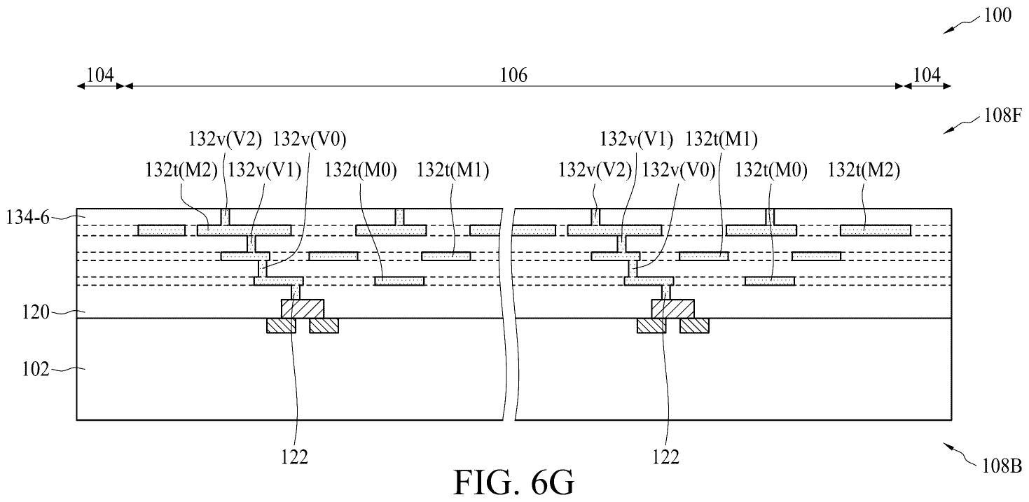

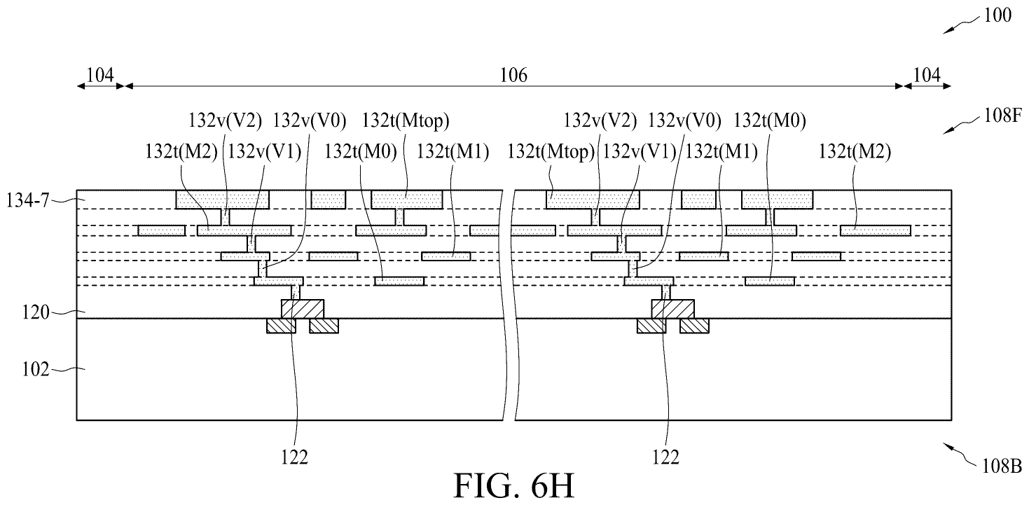

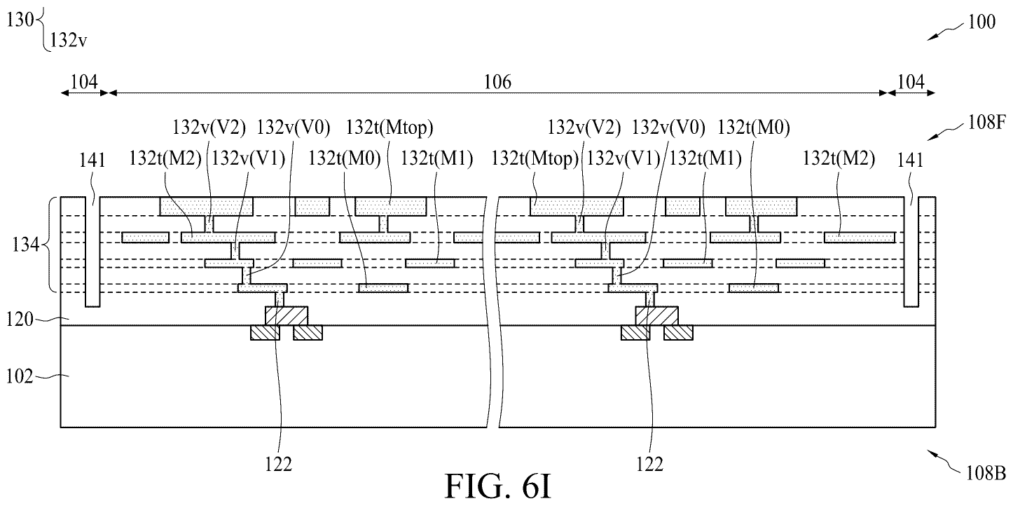

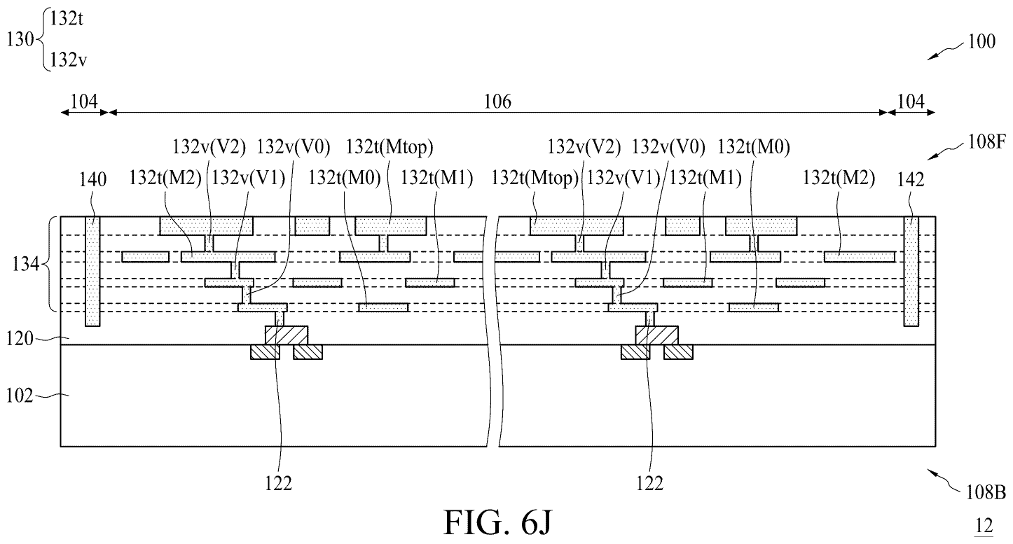

In some embodiments, the metallic edge ring 140 can be formed after the forming of the interconnect structure 130. Please refer to FIGS. 6A to 6J, which are cross-sectional views of various stages in a formation of a semiconductor component structure in accordance with aspects of the present disclosure in one or more embodiments. As shown in FIGS. 6A to 6H, an interconnect structure 130 is formed in the central region 106 of the semiconductor component 100 on the front side 108F. The forming of the interconnect structure 130 may be similar to those described above; therefore, details thereof are omitted for brevity. Additionally, in some embodiments, die seal rings may be formed in each of the die regions in the central region 106, though not shown.

Referring to FIG. 61, in some embodiments, after the forming of the interconnect structure 130 in the central region 106, a metallic edge ring 140 is formed in the peripheral region 104. In some embodiments, a photoresist layer and a hard mask layer may be formed over the substrate 102 on the front side 108F, and a WEE operation is performed to pattern the photoresist layer such that an opening defining a location and a width of the to-be-formed metallic edge ring 140 is formed in the photoresist layer. Such pattern may be transferred to the hard mask layer. In some embodiments, a suitable etch operation may be performed to etch the dielectric layer 134 such that the pattern in the hard mask layer is transferred to the dielectric layer 134 to form a trench 141 corresponding the opening in the photoresist layer. In some embodiments, such etch may be performed on the dielectric layer 134 from the front side 108F of the semiconductor wafer 100 such that a surface of the substrate 102 is exposed though a bottom of the trench 141. A conductive material may be deposited to fill the trench 141, and a planarization may be performed to remove superfluous materials. Accordingly, the metallic edge ring 140 is obtained, as shown in FIG. 6J, which illustrates an intermediate semiconductor package component 12.

In some embodiments, the metallic edge ring 140 includes a material same as that of the interconnect structure 130. In some alternative embodiments, the metallic edge ring 140 includes a material different from that of the interconnect structure 130. As shown in FIG. 6J, a bottom surface of the metallic edge ring 140 is in contact with the substrate 102, and sidewalls of the metallic edge ring 140 are in contact with the dielectric layer 134. In some embodiments, a width of the metallic edge ring 140 is between approximately 0.5 μm and approximately 0.5 mm. For example, the width of the metallic edge ring 140 may be approximately 1 μm, but the disclosure is not limited thereto. In some embodiments, the metallic edge ring 140 has a consistent width, such that the metallic edge ring 140 has straight sidewalls as shown in FIG. 6J, but the disclosure is not limited thereto. In some embodiments, the metallic edge ring 140 is spaced apart from an edge of the semiconductor component 100 by a distance Ds. In some embodiments, the distance Ds is equal to or less than 2.5 mm, but the disclosure is not limited thereto.

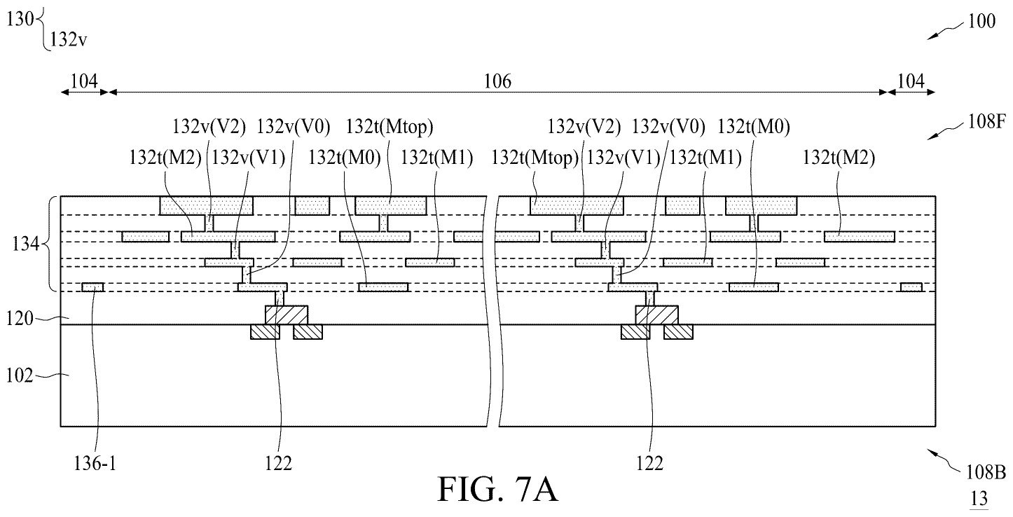

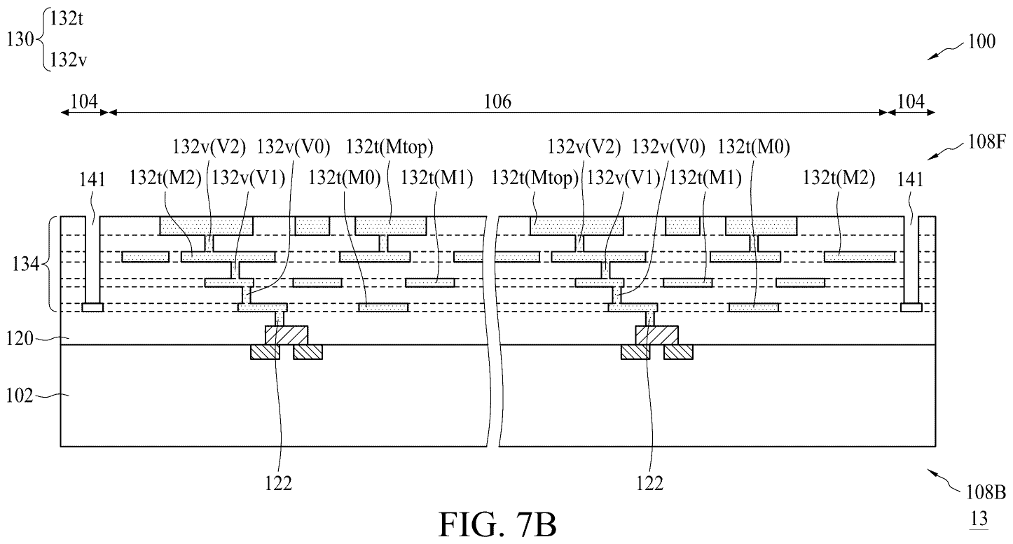

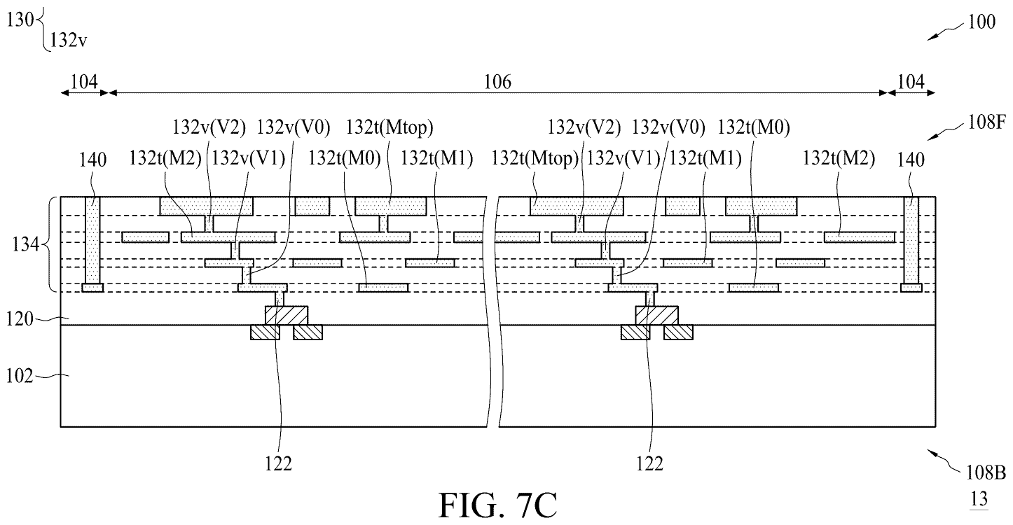

In some embodiments, by modifying the etch operation on the front side 108F of the semiconductor wafer 100, a depth of the trench 141 can be adjusted. For example, the depth of the trench 141 can be kept less than a thickness of the dielectric layer 134. Please refer to FIGS. 7A to 7C, which are cross-sectional views of various stages in a formation of a semiconductor component structure in accordance with aspects of the present disclosure in one or more embodiments. As shown in FIGS. 7A to 7C, an interconnect structure 130 is formed in the central region 106 of the semiconductor component 100 on the front side 108F. The forming of the interconnect structure 130 may be similar to those described above; therefore, details thereof are omitted for brevity. Additionally, in some embodiments, die seal rings may be formed in each of the die regions in the central region 106, though not shown. As shown in FIG. 7A, during the forming of the interconnect structure, a metallization layer 136-1 may be formed in the peripheral region 104 simultaneously with the forming of the 132t (M0).

Referring to FIG. 7B, after the forming of the interconnect structure 130 in the central region 106, a metallic edge ring 140 is formed in the peripheral region 104. In some embodiments, a photoresist layer and a hard mask layer may be formed over the substrate 102 on the front side 108F, and a WEE operation is performed to pattern the photoresist layer such that an opening defining a location and a width of the to-be-formed metallic edge ring 140 is formed in the photoresist layer. Such pattern may be transferred to the hard mask layer. In some embodiments, a suitable etch operation may be performed to etch the dielectric layer 134 such that the pattern in the hard mask layer is transferred to the dielectric layer 134 to form a trench 141 corresponding the opening in the photoresist layer. In some embodiments, such etch may be performed on the dielectric layer 134 from the front side 108F of the semiconductor wafer 100 such that a surface of the metallization layer 136-1 is exposed though a bottom of the trench 141. A conductive material may be deposited to fill the trench 141, and a planarization may be performed to remove superfluous materials. Accordingly, the metallic edge ring 140 that including the metallization layer 136-1 is obtained, as shown in FIG. 7C, which illustrates an intermediate semiconductor package component 13.

A width and a configuration of the metallic edge ring 140 are similar to described above; such details are omitted herein. As shown in FIG. 7, the metallic edge ring 140 is separated from the substrate 102. In some embodiments, sidewalls and a bottom of the metallic edge ring 140 are in contact with the dielectric layer 134. In some embodiments, the bottom of the metallic edge ring 140 may be in contact with the dielectric layer 120, as shown in FIG. 7C, but the disclosure is not limited thereto. For example, in some embodiments, the bottom of the metallic edge ring 140 may be in contact the dielectric layer 134-1, the dielectric layer 134-2, the dielectric layer 134-3, the dielectric layer 134-4, the dielectric layer 134-5 or the dielectric layer 136-6, though not shown.

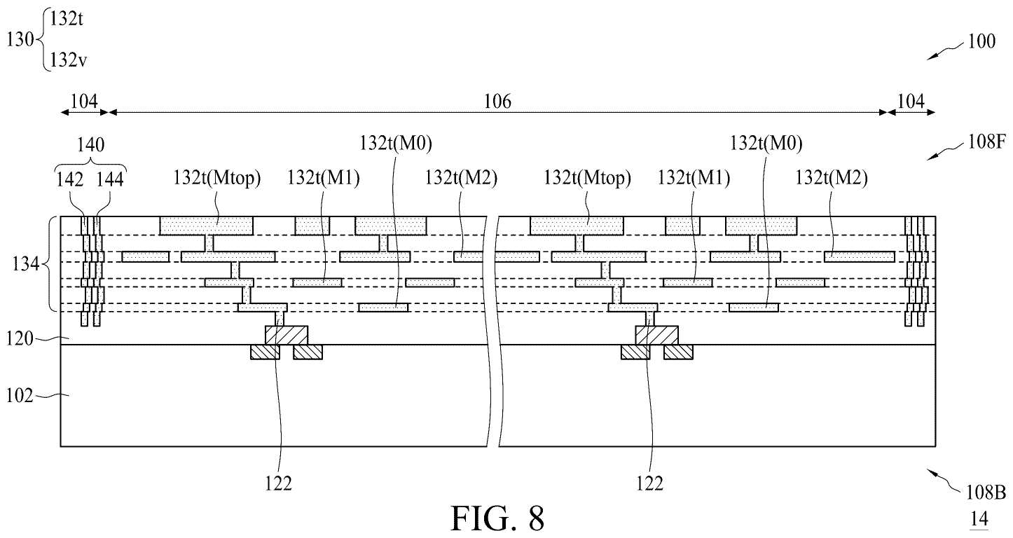

Additionally, a quantity of the metallic edge ring 140 can be adjusted according to various process designs. Referring to FIG. 8, which illustrates an intermediate semiconductor package component 14, in some embodiments, a metallic edge ring 140 is formed in the peripheral region 104. The metallic edge ring 140 may include two portions 142 and 144, as shown in FIG. 8, but the quantity of the metallic edge ring 140 is not limited thereto. The two portions 142 and 144 of the metallic edge ring 140 may have identical widths and configurations, but the disclosure is not limited thereto. In some embodiments, the metallic edge ring 140 may include the portion 142 proximal to an edge of the semiconductor wafer 100, and the portion 144 distal to the edge of the semiconductor wafer 100. In some embodiments, a sum of a width of the portion 142, a spacing distance between the portions 142 and 144, and a width of the portion 144 may be between approximately 0.5 μm and approximately 0.5 mm, but the disclosure is not limited thereto. In some embodiments, the portion 142 is spaced apart from the edge of the semiconductor component 100 by a distance Ds. In some embodiments, the distance Ds is equal to or less than 2.5 mm, but the disclosure is not limited thereto.

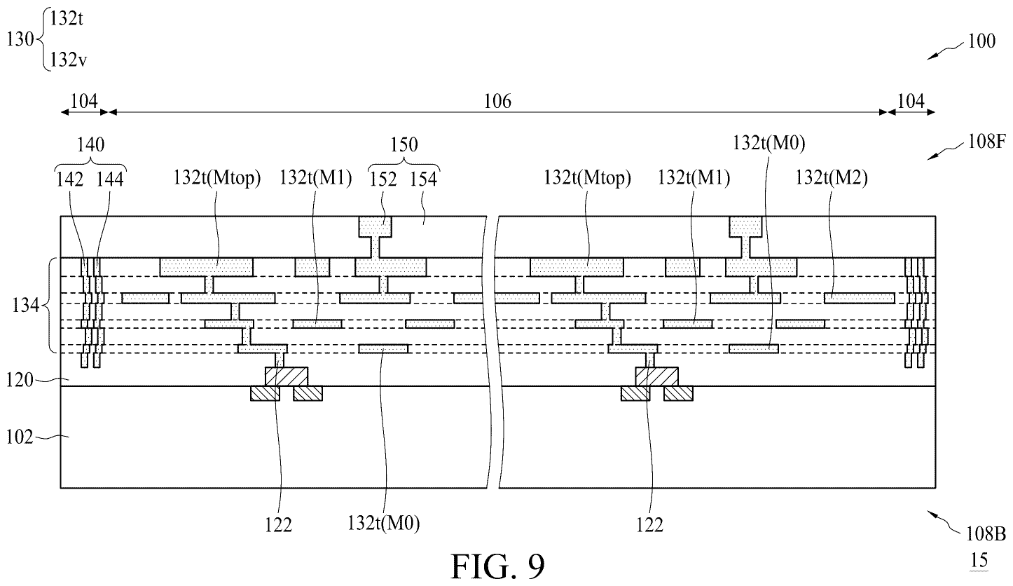

Referring to FIG. 9, which illustrates a semiconductor package component 15 in accordance with some embodiments, a bonding layer 150 is formed over the interconnect structure 130 and the metallic edge ring 140. In some embodiments, a top of the metallic edge ring 140 is in contact with the bonding layer 150. The bonding layer 150 may include a plurality of metallization features such as bonding pads 152 disposed in at least a dielectric layer 154. Some of the bonding pads 152 are electrically connected to the interconnect structure 130, and some of the bonding pads 152 are electrically isolated from the interconnect structure 130. The dielectric layers 154 may include a suitable dielectric material, such as silicon oxide, silicon nitride, or the like. In various embodiments, the dielectric layer 154 may include silicon oxynitride (SiOₓN_{y}). Other suitable dielectric materials may be within the contemplated scope of the disclosure. The bonding pads 152 may include an electrically conductive material that may function as a bonding medium to mechanically bond the semiconductor package component 15 to another semiconductor package component, and may also enable electrical signals to be routed between the semiconductor package component 15 and the bonded semiconductor package component. In various embodiments, the bonding pads 152 may include a metal material, such as copper, a copper alloy, tungsten (W), aluminum (Al), an aluminum alloy, combinations thereof, or the like. Other suitable bonding materials are within the contemplated scope of the disclosure. In some embodiments, a barrier layer (not shown) composed of a suitable barrier material may be formed between the bonding pads 152 and the dielectric layer 154.

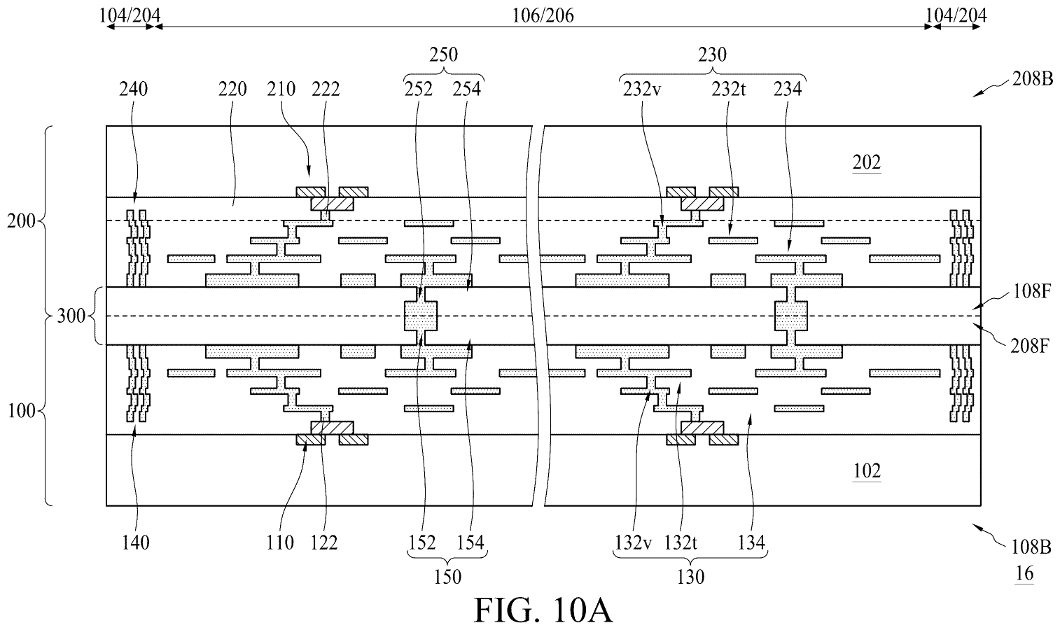

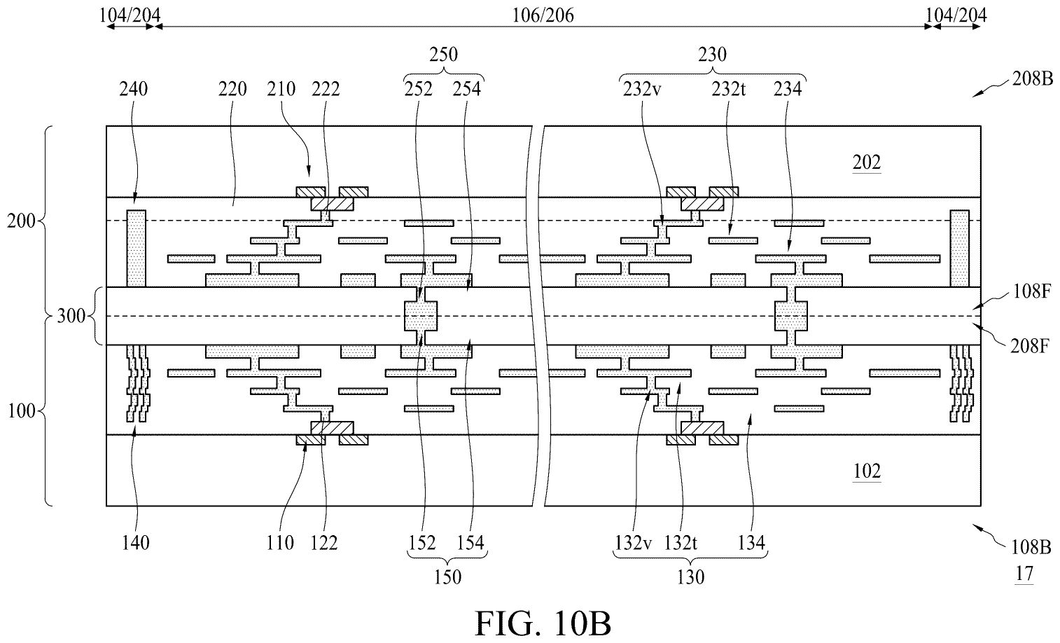

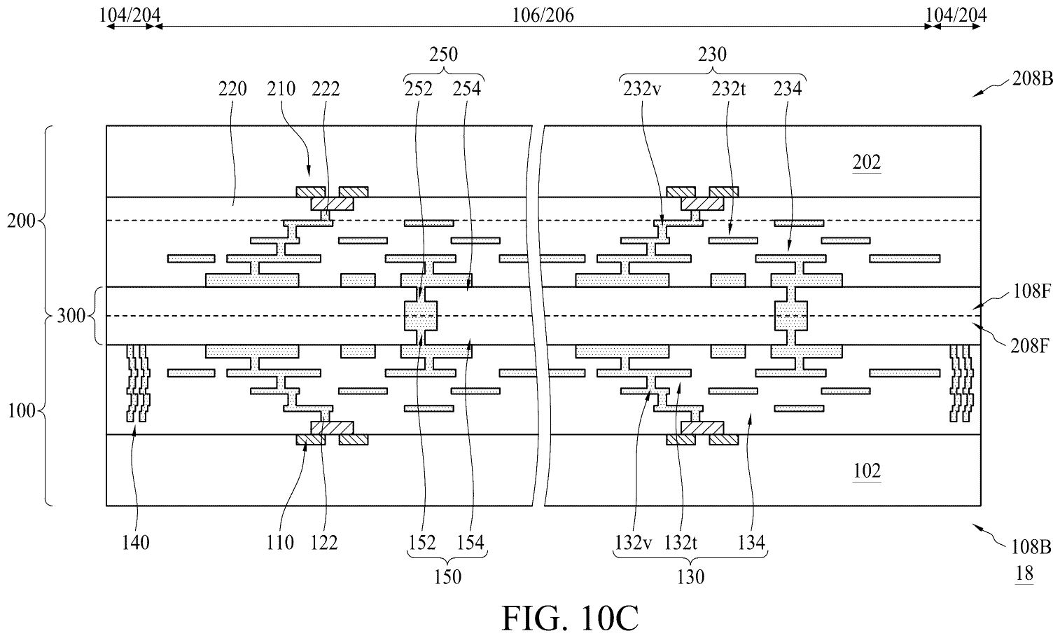

Referring to FIGS. 10A to 10C, which illustrates intermediate semiconductor package structures 16, 17 and 18, respectively, in some embodiments, another semiconductor wafer 200 may be received. In some embodiments, the semiconductor wafer 200 may be similar to the semiconductor wafer 100 and may be formed by the abovementioned processes. In such embodiments, the semiconductor wafer 200 may include a substrate 202. The substrate 202 may include an active surface on a first side (i.e., a front side) 208F, and a second side (i.e., a back side) 208B opposite to the first side 208F. Various microelectronic elements 210 may be formed in the substrate 202 on the front side 208F. Examples of the various microelectronic elements 210 may be formed by a FEOL operation, and similar to described above; therefore, details thereof are omitted herein. The semiconductor wafer 200 may be defined to have a peripheral region 204 and a central region 206 encircled by the peripheral region 204, and the various microelectronic elements 210 are formed in the central region 206. For example, the various microelectronic elements 210 are formed in dies in the central region 206. In some embodiments, a width of the peripheral region 204 may be equal to or less than 3 millimeters, but the disclosure is not limited thereto.

In some embodiments, a MEOL operation may be performed on the first side 208F of the substrate 202 to form an ILD layer 220 and a plurality of connecting structures 222 serving as contact plugs in the ILD layer 220 in the central region 206. In some embodiments, a BEOL operation may be performed on the first side 208F of the substrate 202 to form an interconnect structure 230 electrically connected to the various microelectronic elements 210 in the central region 206. The interconnect structure 230 includes metal lines 232t and vias 232v, which are formed in dielectric layers 234. In some embodiments, a metallic edge ring 240 may be formed in the peripheral region 204 on the front side 208F using the abovementioned operations. In some embodiments, the metallic edge ring 240 is formed simultaneously with the forming of the connecting structure 222 and the interconnect structure 230. In some alternative embodiments, the metallic edge ring 240 is formed after the forming of the interconnect structure 230. Further, the metallic edge ring 240 encircles the interconnect structure 230.

In some embodiments, a configuration and arrangements of the metallic edge ring 240 in the semiconductor wafer 200 may correspond the metallic edge ring 140 in the semiconductor wafer 100. For example but not limited thereto, a metallic edge ring 240 that corresponds to the metallic edge ring 140 is formed in the semiconductor wafer 200 in the peripheral region 204 over the first side 208F. However, in some embodiments, the configuration and the arrangement of the metallic edge ring 240 in the semiconductor wafer 200 may be different from those of the metallic edge ring 140 in the semiconductor wafer 100, as shown in FIG. 10B. In other embodiments, the semiconductor wafer 200 may be free of the metallic edge ring, as shown in FIG. 10C.

In some embodiments, a bonding layer 250 is formed over the interconnect structure 230. The bonding layer 250 may include a plurality of metallization features such as bonding pads 252 disposed in at least a dielectric layer 254. Some of the metallization bonding pads 252 are electrically connected to the interconnect structure 230, and some of the bonding pads 252 are electrically isolated from the interconnect structure 230.

Still referring to FIGS. 10A to 10C, the semiconductor wafer 200 is bonded to the semiconductor wafer 100. In some embodiments, the semiconductor wafer 200 may be bonded to the semiconductor wafer 100 using a hybrid bonding technique. In some embodiments, the surfaces of the semiconductor wafers 100 and 200 may optionally be pre-treated to promote surface activation (e.g., using a plasma treatment process). The semiconductor wafer 200 may be flipped (e.g., inverted) and stacked onto the semiconductor wafer 100 so that the first side 208F of the semiconductor wafer 200 faces the first side 108F of the semiconductor wafer 100, and thus the bonding layer 250 faces the bonding layer 150. The semiconductor wafers 100 and 200 may be aligned such that the metallization features (i.e., the bonding pads) 252 of the semiconductor wafer 200 contact the corresponding metallization features (i.e., the bonding pads) 152 of the semiconductor wafer 100. The bonding pads 252 and the bonding pads 152 are bonded, and the dielectric layers 254 and 154 of the semiconductor wafers 100 and 200 are bonded. In some embodiments, the stack of semiconductor wafers 100 and 200 may then be annealed at an elevated temperature. Accordingly, the bonded dielectric layers 154 and 254 and the bonded metallization features 152 and 252 form a bonded structure 300 between the semiconductor wafer 100 and the semiconductor wafer 200. Further, the semiconductor wafers 100 and 200 are bonded by the bonded structure 300 to form an intermediate semiconductor package structure 16, 17 or 18.

Additionally, the metallic edge ring 140 of the semiconductor wafer 100 is separated from the metallic edge ring 240 of the semiconductor wafer 200 by the bonded structure 300.

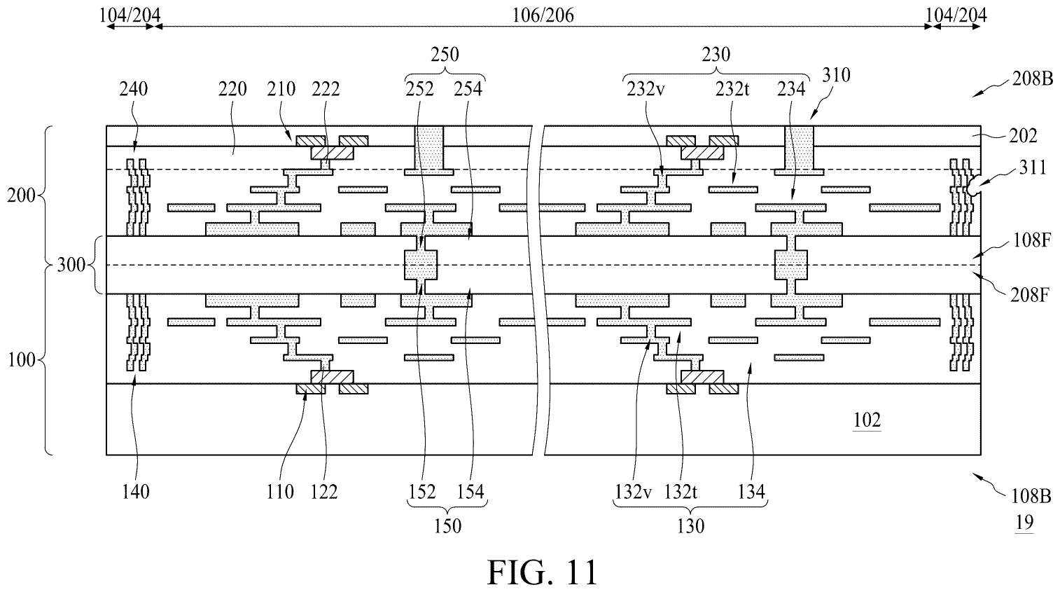

Referring to FIG. 11, in some embodiments, the second side 208B of the substrate 202 may optionally be thinned using a suitable process, such as mechanical grinding, chemical mechanical planarization (CMP), or by an etching process. In some embodiments, a plurality of through-substrate vias 310 are formed in the substrate 202 and the dielectric layers (i.e., the dielectric layers 220 and 234) of the semiconductor wafer 200. In some embodiments, the through-substrate vias 310 are electrically connected to the interconnect structure 230, as shown in FIG. 11.

In some embodiments, a delamination 311 may occur during the bonding of the semiconductor wafers 100 and 200, the thinning of the substrate 202 of the semiconductor wafer 200, and the forming of the through-substrate vias 310. Further, the delamination 311 may occur at the dielectric layer 134 and/or the dielectric layer 234. In some embodiments, such delamination may be exacerbated when the dielectric layer 134 and/or the dielectric layer 234 include ELK materials. It is found that such delamination 311 may start at a circumference/edge of the semiconductor wafer 100 and/or a circumference/edge of the semiconductor wafer 200. In such embodiments, the metallic edge rings 140 and 240 may help to block the delamination from propagating inward to the central region 106/206 where the critical interconnect structures 150 and 250 are formed. In some embodiments, the bonded semiconductor wafers 100 and 200 form a final product for manufacturing a semiconductor package structure 19. In some embodiments, the bonded semiconductor wafers 100 and 200 form an intermediate product for manufacturing the semiconductor package structure 19.

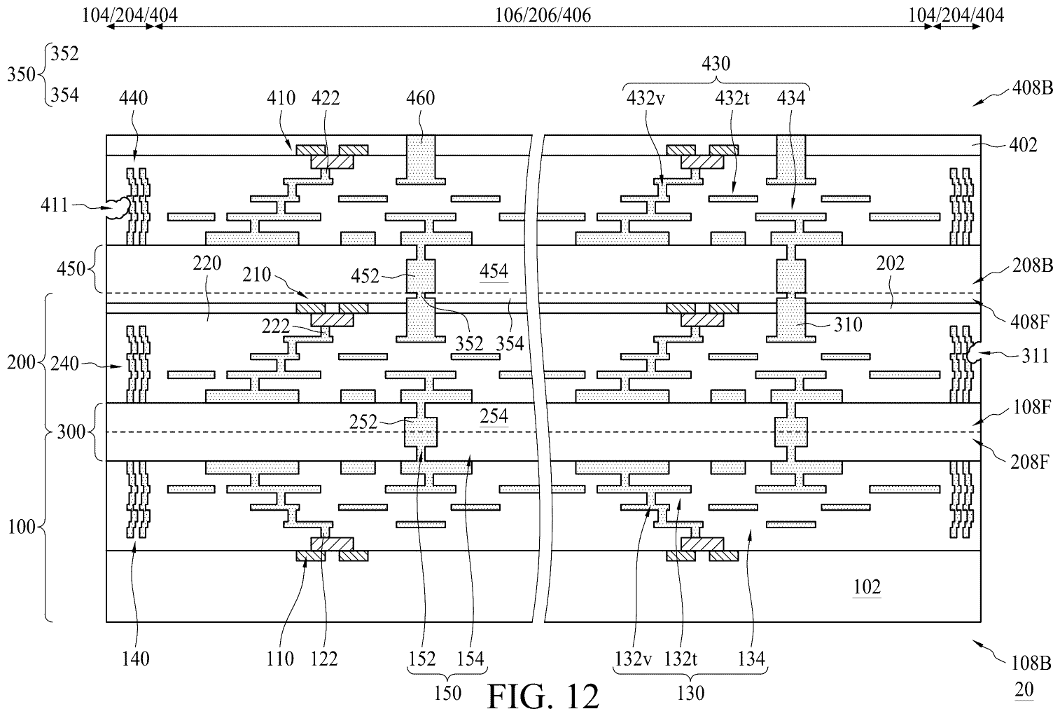

Referring to FIG. 12, in some embodiments, another semiconductor wafer 400 may be received. In some embodiments, the semiconductor wafer 400 may be similar to the semiconductor wafer 100 or 200 described above, and the semiconductor wafer 400 may be formed by the abovementioned processes. In such embodiments, the semiconductor wafer 400 may have a substrate 402, and the substrate 402 may include an active surface on a first side (i.e., a front side) 408F, and a second side (i.e., a back side) 408B opposite to the first side 408F. Various microelectronic elements 410 may be formed in the substrate 402 on the front side 408F. Examples of the various microelectronic elements 410 may be formed by a FEOL operation, and may be similar to the microelectronic elements described above; therefore, details thereof are omitted herein. The semiconductor wafer 400 may be defined to have a peripheral region 404 and a central region 406 encircled by the peripheral region 404, and the various microelectronic elements 410 are formed in the central region 406. In some embodiments, a width of the peripheral region 404 may be equal to or less than 3 millimeters, but the disclosure is not limited thereto.

In some embodiments, a MEOL operation may be performed on the first side 408F of the substrate 402 to form an ILD layer and a plurality of connecting structures 422 serving as contact plugs in the ILD layer 420 in the central region 406. In some embodiments, an operation may be performed on the first side 408F of the substrate 402 to form an interconnect structure 430 electrically connected to the various microelectronic elements 410 in the central region 406. The interconnect structure 430 includes metal lines 432t and vias 432v, which are formed in dielectric layers 434. In some embodiments, a metallic edge ring 440 may be formed in the peripheral region 404 using the abovementioned operations. In some embodiments, the metallic edge ring 440 is formed simultaneously with the forming of the connecting structure 422 and the interconnect structure 430. In some alternative embodiments, the metallic edge ring 440 is formed after the forming of the interconnect structure 430. Further, the metallic edge ring 440 encircles the metallic edge ring 240.

In some embodiments, a configuration and arrangements of the metallic edge ring 440 in the semiconductor wafer 400 may correspond to those of the metallic edge ring 140 in the semiconductor wafer 100. However, in some embodiments, the configuration and the arrangement of the metallic edge ring 440 in the semiconductor wafer 400 may be different from those of the metallic edge ring 140 in the semiconductor wafer 100. In other embodiments, the semiconductor wafer 400 may be free of the metallic edge ring.

In some embodiments, a bonding layer 350 is formed over the substrate 202 on the backside 208B of the semiconductor wafer 200. In some embodiments, the bonding layer 350 may include bonding metallization features such as bonding pads 352 in a dielectric layer 354. Further, the bonding pads 352 may be electrically connected to the through-substrate via 310. In some embodiments, a bonding layer 450 is formed over the BEOL interconnect structure 430 of the semiconductor wafer 400. The bonding layer 450 may include a plurality of metallization features such as bonding pads 452 disposed in at least a dielectric layer 454.

Still referring to FIG. 12, the semiconductor wafer 400 is bonded to the semiconductor wafer 200 of the intermediate semiconductor package structure 19. In some embodiments, the semiconductor wafer 400 may be bonded to the semiconductor wafer 200 using a hybrid bonding technique. In some embodiments, surfaces of the semiconductor wafers 200 and 400 may optionally be pre-treated to promote surface activation (e.g., using a plasma treatment process). The semiconductor wafer 400 may be flipped (e.g., inverted) and stacked onto the semiconductor wafer 200 so that the front side 408F of the semiconductor wafer 400 faces the backside 208B of the semiconductor wafer 200, and thus the bonding layer 450 faces the bonding layer 350. The semiconductor wafers 200 and 400 may be aligned such that the metallization features (i.e., the bonding pads) 452 of the semiconductor wafer 400 contact the corresponding metallization features (i.e., the bonding pads) 352 of the semiconductor wafer 200. The bonding pads 352 and 452 of the semiconductor wafers 200 and 400 are bonded, and the dielectric layers 354 and 454 of the semiconductor wafers 200 and 400 are bonded. Further, the semiconductor wafers 200 and 400, or the intermediate semiconductor package structure 19 and the semiconductor wafer 400, are bonded to form an intermediate semiconductor package structure 20, as shown in FIG. 12. However, in some alternative embodiments, the semiconductor package structure 20 may be a final product.

Additionally, the metallic edge ring 440 of the semiconductor wafer 400 is separated from the metallic edge ring 240 of the semiconductor wafer 200 by the bonded bonding layers 350 and 450, the substrate 202 and a portion of the interconnect structure 230 (i.e., the dielectric layer 234 of the interconnect structure 230).

In some embodiments, the second side 408B of the substrate 402 may optionally be thinned using a suitable process, such as mechanical grinding, chemical mechanical planarization (CMP), or by etching process. In some embodiments, a plurality of through-substrate vias 460 are formed in the substrate 402 and the dielectric layers (i.e., the dielectric layer 434) of the semiconductor component 400. In some embodiments, the through-substrate vias 460 are electrically connected to the interconnect structure 430, as shown in FIG. 12.

In some embodiments, a delamination 411 may occur during the bonding of the semiconductor wafers 200 and 400, the thinning of the substrate 402 of the semiconductor wafer 400, and the forming of the through-substrate vias 460. Further, the delamination 411 may occur at the dielectric layer 134, the dielectric layer 234 and/or the dielectric layer 434. In some embodiments, such delamination 411 may be exacerbated when the dielectric layer 134, the dielectric layer 234 and/or the dielectric layer 434 include ELK materials. It is found that such delamination 411 may start at a circumference/edge of the semiconductor wafer 100, a circumference/edge of the semiconductor wafer 200, and/or a circumference/edge of the semiconductor wafer 400. In such embodiments, the metallic edge rings 140, 240 and/or 440 may help prevent the delamination from propagating inward to the central region 106/206/406 where the critical interconnect structures 150, 250 and 450 are formed.

In some embodiments, further semiconductor package components can be stacked on and bonded to the intermediate semiconductor package structure 20. For example, a semiconductor package structure may include a 4-wafer stack, or a 5-wafer stack, depending on different product designs. It should be noted that every time the intermediate semiconductor package structure undergoes a bonding, a thinning and a through-via formation, the delamination may occur from the circumference/edge of the semiconductor package component(s). However, such delamination is prevented from propagating into the central region by the metallic edge rings disposed in the peripheral regions. Accordingly, good die loss and film peeling issues due to delamination are mitigated.

In some embodiments, a singulation may be performed after the forming of the semiconductor package structure 19, the forming of the semiconductor package structure 20, or the bonding of the semiconductor package structure 20 to other semiconductor package component(s). During such singulation, stress and delamination issues may affect the die seal rings. As mentioned above, the metallic edge ring 140, 240 and 440 provide wafer-level protection during the forming of the semiconductor package structure while the die seal rings provide die-level protection during the singulation of the dies.

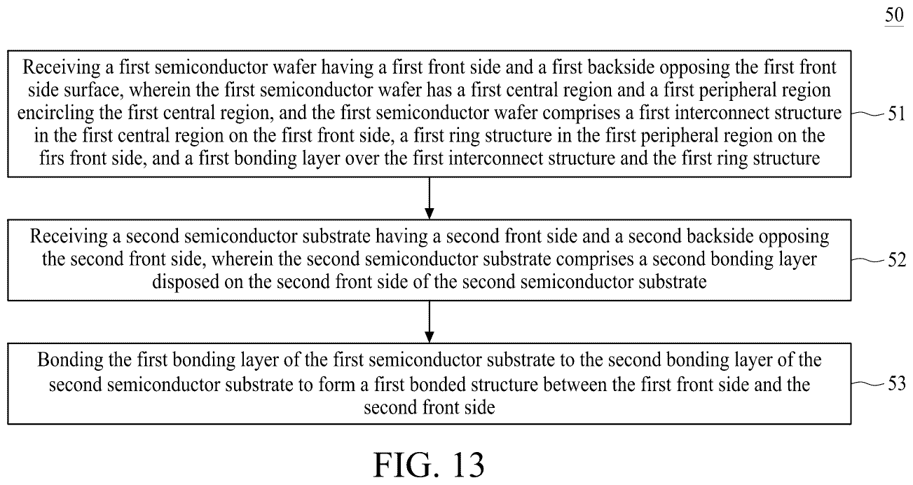

Referring to FIG. 13, a method for forming a semiconductor package structure 50 is provided. While the disclosed method 50 is illustrated and described herein as a series of acts or operations, it will be appreciated that an order of the illustrated acts or operations is not to be interpreted in a limiting sense. For example, some operations may occur in different orders and/or concurrently with other acts or operations apart from those illustrated and/or described herein. In addition, not all illustrated operations may be required to implement one or more aspects or embodiments of the method disclosed herein. Further, one or more of the operations depicted herein may be carried out in one or more separate operations and/or phases.

In operation 51, a first semiconductor wafer is received. In some embodiments, operation 51 includes further operations. For example, please refer to FIGS. 1A and 1B, which are schematic drawings of an intermediate semiconductor package component 10 in accordance with some embodiments corresponding to operation 51. In some embodiments, the intermediate semiconductor package component 10 includes the first semiconductor wafer 100. As described above, the first semiconductor wafer 100 has a front side 108F and a backside 108B opposite to the front side 108F. Further, the first semiconductor wafer 100 has a central region 106 and a peripheral region 104 encircling the central region 106.

In operation 51, an interconnect structure 130 is formed in the central region 106 of the first semiconductor wafer 100. In operation 51, a metallic edge ring is formed in the peripheral region 104 of the first semiconductor wafer 100. In some embodiments, FIGS. 2A to 3J are cross-sectional views of various stages in a formation of intermediate semiconductor structures 10 and 11 in accordance with some embodiments corresponding to operation 51. FIGS. 2A to 5 and FIG. 8 show the various stages when corresponds to operation 51 in other embodiments. Accordingly, the intermediate semiconductor structure 11 includes an interconnect structure 130 in the central region 106 and a metallic edge ring 140 in the peripheral region 104. Additionally, by adjusting the MEOL operation and the BEOL operations, the metallic edge ring 140 may have various configurations and arrangements as shown in the intermediate semiconductor structures 11 and 14 shown in FIGS. 4, 5 and 8.

FIGS. 6A to 6J show the various stages when corresponds to operation 51 in other embodiments. Accordingly, the intermediate semiconductor structure 12 includes an interconnect structure 130 in the central region 106 and a metallic edge ring 140 in the peripheral region 104. Additionally, by adjusting the MEOL and the BEOL operations, the metallic edge ring 140 may have various configurations and arrangements as shown in the intermediate semiconductor structures 13 and 14 shown in FIGS. 7 and 8.

In operation 51, a bonding layer is formed over the metallic edge ring and the interconnect structure on the front side of the semiconductor component. FIG. 9 illustrates a cross-sectional view of an intermediate semiconductor package component 15 in accordance with some embodiments corresponding to operation 51.

In operation 52, a second semiconductor wafer 200 is received. In operation 53, the first semiconductor wafer 100 and the second semiconductor wafer 200 are bonded. FIGS. 10A to 11 are schematic drawings of intermediate semiconductor package structures 16, 17, 18 and 19 in accordance with some embodiments corresponding to operations 52 and 53. As described above, the second semiconductor wafer 200 has a front side 208F and a backside 208B opposite to the front side 208F. Further, the second semiconductor wafer 200 has a central region 206 and a peripheral region 204 encircling the central region 206. In some embodiments, an interconnect structure 230 may be formed on the front side 208F in the central region 206. In some embodiments, a metallic edge ring 240 may be formed on the front side 208F in the peripheral region 204. In some embodiments, the forming of the interconnect structure 230 and the forming of the metallic edge ring 240 are similar to the forming of the interconnect structure 130 and the forming of the metallic edge ring 140. Therefore, details thereof are omitted for brevity.

As shown in FIG. 11, a bonding layer 250 is formed on the backside 208B of the second semiconductor wafer 200. Further, the bonding of the semiconductor wafers 100 and 200 may be performed by bonding the bonding layer 250 to the bonding layer 150, and thus a bonded structure 300 is obtained as shown by the intermediate semiconductor package structure 19.

In some embodiments, the method 50 further includes thinning the second semiconductor wafer 200 from the backside 208B, as shown by the intermediate semiconductor package structure 19 in FIG. 11. In some embodiments, the method 50 further includes forming a through-substrate via 310, as shown by the intermediate semiconductor package structure 13 in FIG. 11.

In some embodiments, the method 50 may include singlating the intermediate semiconductor package structure 19. In some alternative embodiments, the method 50 may include bonding a third semiconductor wafer to the intermediate semiconductor package structure 19. FIG. 12 is a schematic drawing of the intermediate semiconductor component 20 including the third semiconductor wafer 400 in accordance with some embodiments. As described above, the third semiconductor wafer 400 is received. The third semiconductor wafer 400 has a front side 408F and a backside 408B opposing the front side 408F. Further, the semiconductor wafer 400 has a central region 406 and a peripheral region 404 encircling the central region 406. In some embodiments, an interconnect structure 430 may be formed in on the front side 408F in the central region 406. In some embodiments, a metallic edge ring 440 may be formed on the front side 408F in the peripheral region 404. In some embodiments, the forming of the interconnect structure 430 and the forming of the metallic edge ring 440 are similar to the forming of the interconnect structure 430 and the forming of the metallic edge ring 440. Therefore, details thereof are omitted for brevity.

As shown in FIG. 12, a bonding layer 350 may be formed on the backside 308B of the second semiconductor wafer 200, and a bonding layer 450 may be formed on the front side 408F of the semiconductor wafer 400. Further, the bonding of the semiconductor wafer 400 to the intermediate semiconductor package structure 19 may be performed by bonding the bonding layer 450 to the bonding layer 350.

In some embodiments, the method 50 further includes thinning the third semiconductor wafer 400 from the backside 408B, as shown by the intermediate semiconductor package structure 20 in FIG. 12. In some embodiments, the method 50 further includes forming a through-substrate via 460, as shown by the intermediate semiconductor package structure 20 in FIG. 12.

In some embodiments, the method 50 may include singlating the intermediate semiconductor package structure 20. In some alternative embodiments, the method 50 may include bonding one or more semiconductor components to the intermediate semiconductor package structure 20.

In accordance with some embodiments, the present disclosure provides semiconductor package structures and methods of forming the semiconductor package structures, particularly WoW structures. In some embodiments, the semiconductor package structure has a metallic edge ring formed during or after formation of a back-end-of-line (BEOL) interconnect structure. The metallic edge ring helps prevent cracks or delamination from propagating inward to the dies. In some embodiments, to achieve such metallic edge ring scheme, a wafer edge exposure (WEE) operation technique may be performed.

In some embodiments, a method for forming a semiconductor package structure is provided. The method includes following operations. A first semiconductor wafer is received. The first semiconductor wafer includes a first front side and a first backside. The first semiconductor wafer has a first central region and a first peripheral region. The first semiconductor wafer includes a first interconnect structure in the first central region on the first front side, a first ring structure in the first peripheral region on the first front side, and a first bonding layer over the first ring structure and the first interconnect structure on the first front side. A second semiconductor wafer is received. The second semiconductor wafer has a second front side and a second backside. The second semiconductor wafer includes a second bonding layer disposed on the second front side. The first bonding layer is bonded to the second bonding layer.

In some embodiments, a method for forming a semiconductor package component is provided. A semiconductor wafer is received. The semiconductor wafer has a central region and a peripheral region encircling the central region. An interconnect structure is formed in the central region. A metallic edge ring is formed in the peripheral region. A bonding layer is formed over the metallic edge ring and the interconnect structure.

In some embodiments, a semiconductor package structure is provided. The semiconductor package structure includes a first semiconductor wafer, a second semiconductor wafer and a bonded structure. The first semiconductor wafer includes a first semiconductor substrate, a first interconnect structure, and a first metallic edge ring encircling the first interconnect structure. The second semiconductor wafer includes a second semiconductor substrate, a second interconnect structure, and a second metallic edge ring encircling the second interconnect structure. The bonded structure is disposed between the first interconnect structure and the second interconnect structure, and between the first metallic edge ring and the second metallic edge ring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor package structure, comprising:
receiving a first semiconductor wafer having a first front side and a first backside opposite to the first front side, wherein the first semiconductor wafer has a first central region and a first peripheral region encircling the first central region, wherein the first semiconductor wafer comprises:
a first interconnect structure in the first central region on the first front side;
a first ring structure in the first peripheral region on the first front side; and
a first bonding layer over the first ring structure and the first interconnect structure;
receiving a second semiconductor wafer having a second front side and a second backside opposite to the second front side, wherein the second semiconductor wafer comprises a second bonding layer disposed on the second front side; and
bonding the first bonding layer of the first semiconductor wafer to the second bonding layer of the second semiconductor wafer to form a bonded structure between the first front side and the second front side.

2. The method of claim 1, wherein the first ring structure and the first interconnect structure are simultaneously formed.

3. The method of claim 1, further comprising forming the first ring structure after forming the first interconnect structure.

4. The method of claim 1, further comprising:
forming a second ring structure in a second peripheral region of the second semiconductor substrate on the second front side; and
forming a second interconnect structure in a second central region of the second semiconductor substrate on the second front side,
wherein the second peripheral region encircles the second central region, and
wherein the second bonding layer is disposed over the second ring structure and the second interconnect structure.

5. The method of claim 4, wherein the first ring structure is separated from the second ring structure by the bonded structure.

6. The method of claim 1, further comprising forming a third bonding layer over the second backside of the second semiconductor wafer.

7. The method of claim 6, further comprising:
receiving a third semiconductor wafer having a third front side and a third backside opposite to the third front side, wherein the third semiconductor wafer comprises a fourth bonding layer disposed on the third front side; and
bonding the fourth bonding layer of the third semiconductor wafer to the third bonding layer of the second semiconductor wafer.

8. The method of claim 7, further comprising:
forming a third ring structure in a third peripheral region of the third semiconductor substrate on the third front side; and
forming a third interconnect structure in a third central region of the third semiconductor substrate on the third front side,
wherein the third peripheral region encircles the third central region, and
wherein the fourth bonding layer is disposed over the third ring structure and the third interconnect structure.

9. The method of claim 8, wherein the third ring structure is separated from the second ring structure.

10. A method for forming a semiconductor package component, comprising:
receiving a semiconductor wafer, wherein the semiconductor wafer has a central region and a peripheral region encircling the central region;
forming an interconnect structure in the central region;
forming a metallic edge ring in the peripheral region; and
forming a bonding layer over the metallic edge ring and the interconnect structure.

11. The method of claim 10, wherein the forming of the metallic edge ring comprises a wafer edge exposure (WEE) operation.

12. The method of claim 10, wherein the metallic edge ring and the interconnect structure are formed simultaneously.

13. The method of claim 10, wherein the forming of the metallic edge ring is performed after the forming of the interconnect structure.

14. The method of claim 10, wherein a bottom of the metallic edge ring is separated from a substrate of the semiconductor wafer.

15. The method of claim 10, wherein a bottom of the metallic edge ring is in contact with a substrate of the semiconductor wafer.

16. The method of claim 10, wherein a top of the metallic edge ring is separated from the bonding layer.

17. The method of claim 10, wherein a top of the metallic edge ring is in contact with the bonding layer.

18. A semiconductor package structure, comprising:
a first semiconductor wafer comprising:
a first semiconductor substrate;
a first interconnect structure; and
a first metallic edge ring encircling the first interconnect structure;
a second semiconductor wafer comprising:
a second semiconductor substrate;
a second interconnect structure; and
a second metallic edge ring encircling the second interconnect structure; and
a first bonded structure between the first interconnect structure and the second interconnect structure, and between the first metallic edge ring and the second metallic edge ring.

19. The semiconductor package structure of claim 18, wherein the first metallic edge ring is separated from an edge of the first semiconductor substrate, and the second metallic edge ring is separated from an edge of the second semiconductor substrate.

20. The semiconductor package structure of claim 18, further comprising:
a third semiconductor substrate;
a third interconnect structure; and
a third metallic edge ring encircling the third interconnect structure.
